(19) United States
(12) Patent Application Publication
(10) Pub. No.: US 2026/0267234 A1
(43) Pub. Date: Sep. 10, 2026

(54) LITHOGRAPHIC APPARATUS AND ASSOCIATED METHODS

(71) Applicant: ASML NETHERLANDS B.V., Veldhoven (NL)

(72) Inventors: Marcus Adrianus VAN DE KERKHOF, Helmond (NL); Ronald VAN DER HAM, Maarheeze (NL); Dries Els Victor VAN GESTEL, Turnhout (BE); Franciscus Johannes Joseph JANSSEN, Geldrop (NL); Paul Alexander VERMEULEN, Best (NL); Michael ENGEL, Eindhoven (NL); Abraham Jan WOLF, Nuenen (NL); Martin Frans Pierre SMEETS, Veldhoven (NL)

(73) Assignee: ASML NETHERLANDS B.V., Veldhoven (NL)

(21) Appl. No.: 19/167,334

(22) PCT Filed: Mar. 29, 2024
(86) PCT No.: PCT/EP2024/058797

§ 371 Date: Sep. 19, 2025

(30) Foreign Application Priority Data
Apr. 17, 2023 (EP) 23168209.7
Jul. 28, 2023 (EP) 23188348.9

(51) Int. Cl. G03F 7/00; G03F 7/20

(52) U.S. Cl. CPC G03F 7/70466; G03F 7/2004; G03F 7/2022; G03F 7/70033; G03F 7/70066; G03F 7/702; G03F 7/70233; G03F 7/70358; G03F 7/70525; G03F 7/70983

(57) ABSTRACT

A lithographic method includes forming an image of a reticle on a substrate a plurality of times. Each such image formation process includes: illuminating a first portion of a reticle and pellicle assembly with a radiation beam; and projecting radiation scattered by the reticle onto a target region of a substrate using projection optics. The lithographic method further includes periodically illuminating a second portion of the reticle and pellicle assembly with a radiation beam, the second portion of the reticle and pellicle assembly at least partially surrounding the first portion. Some pellicles are susceptible to hydrogen etching and such pellicles tend to fail in a region surrounding a central portion. By periodically illuminating a second portion of the reticle and pellicle assembly with a radiation beam, hydrogen etching of the second portion of the reticle and pellicle assembly may be suppressed.

### CROSS-REFERENCE TO RELATED APPLICATIONS

This application claims priority of EP application 23168209.7 which was filed on 17 Apr. 2023, and EP application 23188348.9 which was filed on 28 Jul. 2023, which are incorporated herein in its entirety by reference.

### FIELD

The present invention relates to an apparatus and associated method for processing or using a reticle and pellicle assembly for use within an extreme ultraviolet (EUV) lithographic apparatus. The present invention also relates to a reticle that may be particularly suitable for use in the apparatus and method for processing a reticle and pellicle assembly. The present invention also relates to a pellicle for use in a lithographic apparatus. The present invention also relates to a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g., a mask) onto a layer of radiation-sensitive material (resist) provided on a substrate.

The wavelength of radiation used by a lithographic apparatus to project a pattern onto a substrate determines the minimum size of features that can be formed on that substrate. A lithographic apparatus that uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A patterning device (e.g., a mask) that is used to impart a pattern to a radiation beam in a lithographic apparatus may form part of a mask assembly. A mask assembly may include a pellicle that protects the patterning device from particle contamination. The pellicle may be supported by a pellicle frame.

It may be desirable to provide an apparatus that obviates or mitigates one or more problems associated with the prior art.

### SUMMARY

According to a first aspect of the present disclosure there is provided a lithographic method comprising: forming an image of a reticle on a substrate a plurality of times, each such image formation process comprising: illuminating a first portion of a reticle and pellicle assembly with a radiation beam; and collecting radiation scattered by the reticle and projecting it onto a target region of a substrate using projection optics; and periodically illuminating a second portion of the reticle and pellicle assembly with a radiation beam, the second portion of the reticle and pellicle assembly at least partially surrounding the first portion.

The lithographic method according to the first aspect is advantageous, as now discussed.

Any contamination on the reticle will, in general, alter the image formed on the substrate, leading to printing errors. To avoid particle contamination of reticles, it is known to use a thin membranes, known as a pellicle, to protect the reticle. The pellicle is disposed in front of the reticle and prevents particles from landing on the reticle. The pellicle is disposed such that it is not sharply imaged onto the substrate (e.g. a resist-coated wafer) and therefore particles on the pellicle are less likely to interfere with the imaging process than particles on the reticle would be. One particularly promising material for use as a pellicle membrane in an EUV lithographic apparatus is a fabric of carbon nanotubes (CNTs), which can provide very high EUV transmission (of >98%) and a very good mechanical stability. However, a low pressure hydrogen gas is typically provided within the lithographic apparatus, which forms a hydrogen plasma in the presence of the EUV radiation (during exposure). It has been found that this hydrogen ions and hydrogen free radicals from the hydrogen plasma can etch pellicles formed from CNTs, limiting the potential lifetime of the pellicle and blocking commercial implementation of CNT pellicles.

It has been found that the etching of carbon by hydrogen ions and free radicals is temperature dependent. In particular, it has been found that: (a) the carbon etching rate is non-zero at lower temperatures; (b) the carbon etching rate falls to a negligible level at a threshold temperature, above which the carbon etching remains at a negligible level; and (c) a pellicle within an EUV lithographic scanner will typically cycle through a range of temperatures sampling temperatures at which the carbon etching rate is not negligible during each cycle. For example, in an EUV lithographic scanner, during operation, an EUV radiation beam may scan back and forth over the pellicle, which leads to permanent temperature fluctuations.

It has also been found that once a pellicle has been heated to above a threshold level (at which hydrogen etching becomes negligible), once the heating is removed, there is a time delay before the etching rate increases from the negligible level. It is thought that heating to a sufficient temperature causes desorption of hydrogen from the pellicle, which reduces the hydrogen etching rate to negligible levels. Furthermore, it is thought that the time delay in the increase in the etching rate after removal of the heating is because it takes a non-zero time for the surfaces of the pellicle to be replenished with hydrogen following the heating.

The first portion of a reticle and pellicle assembly is the part that is illuminated (EUV) radiation to form an image of the reticle on the substrate. Therefore, the first portion of the reticle and pellicle assembly may comprise an image formation portion of the reticle and a corresponding portion of the pellicle. The first portion of the reticle and pellicle assembly is exposed to EUV radiation during each image formation process. This will result in heating of the first portion of the reticle and pellicle assembly (for a lithographic scanner, each part of the first portion of the reticle and pellicle assembly will be heated periodically, with a periodicity given by the rate at which images are formed, i.e. once per die). As will be appreciated by the skilled person, within a lithographic apparatus, the hydrogen plasma is formed by the EUV radiation (used for exposure of the substrate). Therefore, the hydrogen plasma is formed in the vicinity of the first portion of the reticle and pellicle assembly, which is exposed to EUV radiation and which is heated by the EUV radiation. It will be further appreciated that the plasma may extend to surrounding regions, which are not heated directly by the EUV radiation. As a result, the inventors have found that pellicles tend to fail in a region surrounding a central portion (that corresponds to the image formation portion).

Advantageously, by periodically illuminating a second portion of the reticle and pellicle assembly with a radiation beam, hydrogen etching of the second portion of the reticle and pellicle assembly (which at least partially surrounds the first portion) can be suppressed.

It will be appreciated that as used herein the second portion partially surrounding the first portion is intended to mean that the second portion is adjacent to the first portion. It will be appreciated that as used herein the second portion being adjacent to the first portion is intended to mean that the first and second portions are in contact, or share a common boundary, for at least a portion of the first portion. The second portion may extend along, and be adjacent to, at least one side of the first portion (which may be generally rectangular). The second portion may extend along, and be adjacent to, more than one side of the first portion (which may be generally rectangular). In some embodiments, the second portion may completely surround the first portion. That is, the second portion may extend along, and be adjacent to, all (four) sides of the first portion (which may be generally rectangular).

Periodically illuminating the second portion of the reticle and pellicle assembly with a radiation beam may be achieved by periodically illuminating an enlarged exposure field.

The exposure field is a region of the reticle and pellicle assembly that is exposed to radiation. It will be appreciated that an extent of the exposure field in a non-scanning direction may be defined by an extent of the radiation beam in the non-scanning direction (which may be defined by a pair of masking blades). It will be appreciated that an extent of the exposure field in a scanning direction may be defined by both an extent of the radiation beam in the scanning direction (which may be defined by a pair of masking blades) and an extent of the scanning motion.

The illumination of such an enlarged field may be part of the exposure of a target region of the substrate (i.e. part of an image formation process). Alternatively, the illumination of an enlarged field may be in between exposure of two target regions of a substrate (i.e. in between two image formation processes). For example, the illumination of an enlarged field may occur in between exposures of different target regions (or dies) of a single substrate or even in between exposures of different substrates.

Periodically illuminating the second portion of the reticle and pellicle assembly with a radiation beam may be achieved by varying the exposure field.

It will be appreciated that an extent and/or position of the exposure field may be varied.

The exposure field for at least some image formation processes may be different to the exposure field for a previous image formation process.

A least one edge of the exposure field for each at least some image formation processes may be shifted by an offset.

For example, the offset may be of the order of 50 um. At least one of the edges of the exposure field may be stepped by such an offset every n exposure processes (for example every exposure process). In some embodiments all edges of the exposure field may be stepped by such an offset. The method may use, for example, of the order of 5 different positions for each edge of the exposure field and the positions of each edge of the exposure field may be stepped or cycled through all of the (for example 5) different positions.

The exposure field for the plurality of image formation processes may be continuously varying.

For example, a position of at least one edge of the exposure field may be continuously varying. For example, a position of at least one edge of the exposure field may oscillate over a range of positions about a nominal position. An amplitude of such oscillation may be of the order of 100 μm. In some embodiments all edges of the exposure field may be continuously varying.

During each image formation process at least one masking blade may be used so as to mask an adjacent target region of the substrate from the radiation beam.

Preferably, four masking blades may be used so as to define an exposure region and to mask adjacent target regions on all four sides of the exposure region. The exposure field may be defined by the exposure region, a scanning length, and the positions of the four masking blades.

In some embodiments, illuminating an enlarged exposure field or varying the exposure field may be achieved by controlling the at least one masking blade.

A position of the at least one reticle masking blade may be manipulated such that a perimeter line of the exposure region is spread out over an extended area.

For example, the perimeter line of the exposure region may be spread out over an area having a dimension of the order of 100 μm.

In some embodiments, four masking blades may be used during the exposure of each target region so as to define the exposure field and for each target region adjacent to an edge of the substrate at least one of the masking blades that corresponds to an edge of the exposure field that is adjacent the edge of the substrate may be positioned so as to enlarge the exposure field.

The target regions that are adjacent to the edge of the substrate may be referred to as edge target regions or edge dies. It will be appreciated that such edge target regions do not have adjacent target regions on all sides. Rather, on at least one side (adjacent the edge of the substrate), each edge target region has no adjacent neighbour target region. For such edge target regions (or dies) on the substrate, the masking blades may be positioned so as to enlarge the exposure region. For example, for such edge target regions (or dies) on the substrate, the masking blades may be shifted by 1 mm or more relative to a nominal position so as to enlarge the exposure region. Advantageously, this will result in illumination of a portion of the reticle and pellicle assembly with a radiation beam that is adjacent to the first portion of the reticle and pellicle assembly. If the masking blades are controlled in this way for all such edge dies, a portion of the reticle and pellicle assembly that substantially surrounds the first portion of the reticle and pellicle assembly can be illuminated with radiation.

Forming an image of a reticle on a substrate a plurality of times may comprise forming an image of the reticle on a plurality of target regions of the substrate. Each of the plurality of target regions may be generally rectangular. The plurality of target regions may be arranged as a two-dimensional array.

In some embodiments, the two-dimensional array of target regions may be exposed using a standard meander scan pattern in which each row of target regions (extending in a non-scanning direction) is exposed in turn. One target region from each row has no adjacent target region on one side and another target region has no adjacent target region on the other side. Therefore, with such an arrangement, portions of the reticle and pellicle assembly that are adjacent to the first portion of the reticle and pellicle assembly but offset in the non-scanning direction can be exposed to radiation during exposure of each row. In contrast, during exposure of the first half of the substrate there are some target regions that have no adjacent target region on a first side in the scanning direction but there are no target regions that have no adjacent target region on the other (second) side in the scanning direction. Similarly, during exposure of the first half of the substrate there are some target regions that have no adjacent target region on the second side in the scanning direction but there are no target regions that have no adjacent target region on the first side in the scanning direction.

In some embodiments, the two-dimensional array of target regions may be exposed using an exposure pattern in which the plurality of rows of target regions (extending in a non-scanning direction) are exposed in a different order in order to increase the frequency with which target regions having no adjacent target region on the first or second side in the scanning direction is increased.

Forming an image of a reticle on a substrate a plurality of times may comprise forming an image of the reticle on a plurality of target regions of the substrate, the plurality of target regions arranged as a two-dimensional array, wherein the two-dimensional array of target regions may be exposed one row at a time and wherein the rows may be exposed not in order.

Each image formation process may comprise a scanning exposure in which the reticle and pellicle assembly is moved in a scanning direction relative to the radiation beam.

For embodiments wherein an enlarged exposure field is periodically illuminated, the radiation scattered from the reticle and pellicle assembly from said enlarged exposure field may be not projected onto the substrate.

For example, in some embodiments, the substrate may be moved such that the radiation scattered from the reticle and pellicle assembly is not incident on the substrate. Alternatively, in some embodiments, a shutter may be closed so as to prevent the radiation scattered from the reticle and pellicle assembly from being incident on the substrate.

In general, a duration of the periodic illumination of the second portion of the reticle and pellicle assembly with a radiation beam may be sufficiently large to heat the second portion of the pellicle to a desired temperature (for example above a threshold temperature above which hydrogen etching of the pellicle is negligible). In some embodiments, the desired temperature may be above 900 K. It will be appreciated that the time required for heating the pellicle to a desired temperature will be dependent on a power of the radiation beam while it is heating the pellicle.

Periodically illuminating a second portion of the reticle and pellicle assembly with a radiation beam may comprise exposing the second portion to EUV radiation to heat up the pellicle to a temperature at which a hydrogen etching rate of the pellicle is negligible.

For example, periodically illuminating a second portion of the reticle and pellicle assembly with a radiation beam may comprise exposing the second portion to EUV radiation to heat up the pellicle to a temperature above 800 K, for example a temperature above 900 K.

In general, a time period between two consecutive illuminations of the second portion of the reticle and pellicle assembly with a radiation beam may be sufficiently small so as to not allow a surface of the pellicle to become replenished with hydrogen following the heating from the first illumination. Again, it will be appreciated that the time required for the surface of the pellicle to become replenished with hydrogen following the heating from the first illumination will be dependent on conditions in the vicinity of the pellicle. In some embodiments, a time period between two consecutive illuminations of the second portion of the reticle and pellicle assembly may be of the order of 100 ms.

Periodically illuminating the second portion of the reticle and pellicle assembly with a radiation beam may be such that the second portion of the reticle and pellicle assembly is illuminated once per substrate.

Periodically illuminating the second portion of the reticle and pellicle assembly with a radiation beam may be such that the second portion of the reticle and pellicle assembly is illuminated once per each row of target regions on a substrate.

According to a second aspect of the present disclosure there is provided a lithographic component of a lithographic apparatus, the lithographic component comprising: a support structure constructed to support a reticle and pellicle assembly for receipt of a radiation beam; and a controller operable to control the support structure and/or the radiation beam so as to: (a) form an image of a reticle supported by the support structure on a substrate a plurality of times, each such image formation process comprising: illuminating a first portion of a reticle and pellicle assembly with the radiation beam; and projecting radiation scattered by the reticle onto a target region of a substrate using projection optics; and (b) periodically illuminate a second portion of the reticle and pellicle assembly with the radiation beam, the second portion of the reticle and pellicle assembly at least partially surrounding the first portion.

The lithographic component according to the second aspect is advantageous, as now discussed.

As discussed above, a pellicle disposed in front of the reticle can prevent particles from landing on the reticle, which can improve optical performance (by reducing printing errors). One particularly promising material for use as a pellicle membrane in an EUV lithographic apparatus is a fabric of carbon nanotubes (CNTs), however, CNT pellicles are susceptible to hydrogen etching. It has been found that the etching of carbon by hydrogen ions and free radicals falls to a negligible level at a threshold temperature, above which the carbon etching remains at a negligible level. It has also been found that once a pellicle has been heated to above a threshold level (at which hydrogen etching becomes negligible), once the heating is removed, there is a time delay before the etching rate increases from the negligible level.

The first portion of a reticle and pellicle assembly is the part that is illuminated (EUV) radiation to form an image of the reticle on the substrate. Therefore, the first portion of the reticle and pellicle assembly may comprise an image formation portion of the reticle and a corresponding portion of the pellicle. The first portion of the reticle and pellicle assembly is exposed to EUV radiation during each image formation process. This will result in heating of the first portion of the reticle and pellicle assembly (for a lithographic scanner, each part of the first portion of the reticle and pellicle assembly will be heated periodically, with a periodicity given by the rate at which images are formed, i.e. once per die). As will be appreciated by the skilled person, within a lithographic apparatus, the hydrogen plasma is formed by the EUV radiation (used for exposure of the substrate). Therefore, the hydrogen plasma is formed in the vicinity of the first portion of the reticle and pellicle assembly, which is exposed to EUV radiation and which is heated by the EUV radiation. It will be further appreciated that the plasma may extend to surrounding regions, which are not heated directly by the EUV radiation. As a result, the inventors have found that pellicles tend to fail in a region surrounding a central portion (that corresponds to the image formation portion).

Advantageously, by periodically illuminating a second portion of the reticle and pellicle assembly with a radiation beam, hydrogen etching of the second portion of the reticle and pellicle assembly (which at least partially surrounds the first portion) can be suppressed.

The controller may be operable to implement the method of the first aspect of the present disclosure.

The lithographic component may further comprise a scanning mechanism operable to move the support structure relative to the radiation beam in a scanning direction.

The scanning mechanism may be further operable to move a substrate table of a lithographic apparatus relative to a projection system of the lithographic apparatus such that an image of a reticle formed by the projection system is substantially stationary with respect to the substrate. This may be described as synchronized movement of the support structure and substrate table. The movement (direction and speed) of the substrate table relative to the support structure will, in general, be dependent on the image reversal and magnification properties of the projection system.

The controller may be operable to control the scanning mechanism.

The lithographic component may further comprise: a first pair of masking blades arranged to define an extent of an exposure region in a first direction; and a second pair of masking blades arranged to define an extent of an exposure region in a second direction.

The first and second pair of masking blades may be movable so as to vary the extent of the exposure region. The controller may be operable to control a position of each of the first and second pair of masking blades. In use, the two pairs of masking blades may be used so as to define the exposure region and to mask adjacent target regions on all four sides of the exposure region.

The first direction may be the scanning direction and in order to form an image of a reticle supported by the support structure on target region of a substrate, the controller may be operable to: control the scanning mechanism so as to move a reticle supported by the support structure through an exposure region; and control a position of the first pair of masking blades so as to mask an adjacent target region of the substrate from the radiation beam.

As the target region of the substrate moves into the exposure region, the first pair of masking blades moves such that only the target region receives radiation (i.e. no parts of the substrate outside of the target region are exposed). At the start of the scanning exposure one of the first pair of masking blades is disposed in the path of the radiation beam, acting as a shutter, such that no part of the substrate receives radiation. At the end of the scanning exposure the other one of the first pair of masking blades is disposed in the path of the radiation beam, acting as a shutter, such that no part of the substrate receives radiation. During a middle part of the scanning exposure, when there is no overlap between the exposure region (which receives the radiation) and either of the adjacent target regions of the substrate, both of the first pair of masking blades are disposed in retracted positions.

In order to illuminate the second portion of the reticle and pellicle assembly with the radiation beam, the controller may be operable to control the first and/or second pair of masking blades so as to illuminate an enlarged exposure field.

The exposure field is a region of the reticle and pellicle assembly that is exposed to radiation. It will be appreciated that an extent of the exposure field in a non-scanning direction may be defined by an extent of the radiation beam in the non-scanning direction (which may be defined by a pair of masking blades). It will be appreciated that an extent of the exposure field in a scanning direction may be defined by both an extent of the radiation beam in the scanning direction (which may be defined by a pair of masking blades) and an extent of the scanning motion.

The illumination of such an enlarged field may be part of the exposure of a target region of the substrate (i.e. part of an image formation process). Alternatively, the illumination of an enlarged field may be in between exposure of two target regions of a substrate (i.e. in between two image formation processes). For example, the illumination of an enlarged field may occur in between exposures of different target regions (or dies) of a single substrate or even in between exposures of different substrates.

In order to illuminate the second portion of the reticle and pellicle assembly with the radiation beam, the controller may be operable to control the first and/or second pair of masking blades so as to vary the exposure field.

It will be appreciated that an extent and/or position of the exposure field may be varied.

The controller may be operable to control the first and/or second pair of masking blades so such that the exposure field for at least some image formation processes is different to the exposure field for a previous image formation process.

For example, the controller may be operable to control the first and/or second pair of masking blades so that at least one edge of the exposure field for each at least some image formation processes is shifted by an offset.

For example, the offset may be of the order of 50 um. At least one of the edges of the exposure field may be stepped by such an offset every n exposure processes (for example every exposure process). In some embodiments all edges of the exposure field may be stepped by such an offset. A method implemented by the controller may use, for example, of the order of 5 different positions for each edge of the exposure field and the positions of each edge of the exposure field may be stepped or cycled through all of the (for example 5) different positions.

The controller may be operable to control the first and/or second pair of masking blades such that the exposure field for the plurality of image formation processes is continuously varying.

For example, a position of at least one edge of the exposure field may be continuously varying. For example, a position of at least one edge of the exposure field may oscillate over a range of positions about a nominal position. An amplitude of such oscillation may be of the order of 100 μm. In some embodiments all edges of the exposure field may be continuously varying.

In order to illuminate the second portion of the reticle and pellicle assembly with the radiation beam, the controller may be operable to control the first and/or second pair of masking blades such that a perimeter line of the exposure region is spread out over an extended area.

For example, the perimeter line of the exposure region may be spread out over an area having a dimension of the order of 100 μm.

In order to illuminate the second portion of the reticle and pellicle assembly with the radiation beam, the controller may be operable to control the first and/or second pair of masking blades such that when forming an image of a reticle supported by the support structure on a target region of a substrate that is adjacent to an edge of the substrate, at least one of the masking blades that corresponds to an edge of the exposure field that is adjacent the edge of the substrate is positioned so as to enlarge the exposure field.

The target regions that are adjacent to the edge of the substrate may be referred to as edge target regions or edge dies. It will be appreciated that such edge target regions do not have adjacent target regions on all sides. Rather, on at least one side (adjacent the edge of the substrate), each edge target region has no adjacent neighbour target region. For such edge target regions (or dies) on the substrate, the masking blades may be positioned so as to enlarge the exposure region. For example, for such edge target regions (or dies) on the substrate, the masking blades may be shifted by 1 mm or more relative to a nominal position so as to enlarge the exposure region. Advantageously, this will result in illumination of a portion of the reticle and pellicle assembly with a radiation beam that is adjacent to the first portion of the reticle and pellicle assembly. If the masking blades are controlled in this way for all such edge dies, a portion of the reticle and pellicle assembly that substantially surrounds the first portion of the reticle and pellicle assembly can be illuminated with radiation.

Forming an image of a reticle on a substrate a plurality of times may comprise forming an image of the reticle on a plurality of target regions of the substrate. Each of the plurality of target regions may be generally rectangular. The plurality of target regions may be arranged as a two-dimensional array.

In general, a duration of the periodic illumination of the second portion of the reticle and pellicle assembly with a radiation beam may be sufficiently large to heat the second portion of the pellicle to a desired temperature (for example above a threshold temperature above which hydrogen etching of the pellicle is negligible). In some embodiments, the desired temperature may be above 900 K. It will be appreciated that the time required for heating the pellicle to a desired temperature will be dependent on a power of the radiation beam while it is heating the pellicle.

When illuminating the second portion of the reticle and pellicle assembly with the radiation beam, the controller may be operable to heat up the pellicle to a temperature at which a hydrogen etching rate of the pellicle is negligible.

For example, the controller may be operable to heat up the pellicle to a temperature above 800 K, for example a temperature above 900 K.

According to a third aspect of the present disclosure there is provided a lithographic apparatus comprising the component of the second aspect of the present disclosure.

The lithographic apparatus may further comprise: an illumination system configured to condition the radiation beam received by the reticle and pellicle assembly; a substrate table constructed to support a substrate; and a projection system configured to receive the radiation beam from the reticle and pellicle assembly and to project said radiation beam onto the substrate.

According to a fourth aspect of the present disclosure there is provided a pellicle for use in a lithographic apparatus, pellicle comprising: a frame; and a membrane surrounded by, and supported by, the frame; wherein the membrane is generally planar and defines a plane of the pellicle; wherein the frame has a thickness that is generally perpendicular to the plane of the pellicle and a width that is generally parallel to the plane of the pellicle; and wherein, in the plane of the pellicle, an outer portion of the frame is in contact with the membrane and, along at least one edge of the membrane, an inner portion of the frame has a reduced thickness relative to the outer portion of the frame such that the inner portion of the frame is not in contact with the membrane.

In use, the membrane will receive a heat load from the radiation used by the lithographic apparatus (for example EUV radiation) whereas the frame will remain at a lower temperature. The region of the membrane that is in contact with the frame has a reduced temperature due to the presence of the frame (which has greater thermal inertia than the membrane due to its larger dimensions). The pellicle according to the fourth aspect of the present disclosure is advantageous as it allows for a contact between the frame and the membrane to be moved outwards along at least one edge of the membrane without reducing a width of the frame (i.e. a dimension of the frame that is generally parallel to the plane of the pellicle). This allows the frame to retain a similar level of rigidity whilst moving the contact between the frame and the membrane outwards. Furthermore, advantageously, by moving the portion of the membrane that is in contact with the frame (and which, in use, is at a lower temperature than the rest of the membrane) outwards the membrane is exposed to less, or even no, high intensity EUV-induced hydrogen plasma.

A recess formed between the inner portion of the frame having a reduced thickness and the membrane may have a generally uniform thickness.

Alternatively, a recess formed between the inner portion of the frame having a reduced thickness and the membrane may have a thickness that varies from an inner edge of the frame to the outer portion of the frame.

It will be appreciated that a width of the inner portion of the frame having a reduced thickness may be chosen such that the portion of the membrane that is in contact with the frame (and which, in use, is at a lower temperature than the rest of the membrane) is not adjacent to a high intensity EUV-induced hydrogen plasma.

A width of the inner portion of the frame having a reduced thickness may be greater than 2 mm.

A width of the inner portion of the frame having a reduced thickness may be greater than 2.2 mm. In some embodiments, a width of the inner portion of the frame having a reduced thickness may be of the order of 2.5 mm.

According to a fifth aspect of the present disclosure there is provided a lithographic apparatus comprising: a pellicle comprising: a frame; and a membrane surrounded by, and supported by, the frame; a source of hydrogen; and an illumination system arranged to illuminate the pellicle with radiation; wherein a portion of the membrane that is in contact with the frame is disposed in a position that an EUV-induced hydrogen plasma does not diffuse to.

Advantageously, since the portion of the membrane that is in contact with the frame is disposed in a position that an EUV-induced hydrogen plasma does not diffuse to, the membrane is subject to less etching from the plasma. The pellicle of lithographic apparatus according to the fifth aspect of the present disclosure may comprise a pellicle according to the fourth and/or sixth aspects of the present disclosure.

According to a sixth aspect of the present disclosure there is provided a pellicle for use in a lithographic apparatus, pellicle comprising: a frame; a membrane surrounded by, and supported by, the frame; and a shield adjacent to a peripheral portion of the membrane that is adjacent the frame; wherein the membrane is generally planar and defines a plane of the pellicle; and wherein the shield is spaced apart from the membrane in a direction generally perpendicular to the plane of the pellicle.

The pellicle according to the sixth aspect of the present disclosure is advantageous as the shield can protect the pellicle from etching by plasma (for example EUV-induced hydrogen plasma) in use, for example in an EUV lithographic apparatus.

Conventional thought may be that the reticle masking blades may act as a plasma shield for the pellicle. However, recently it has been found that the region of highest etching on CNT membranes is outside the exposure area, under the reticle masking blades (indicating that the reticle masking blades do not provide effective plasma shielding of the pellicle). It is thought that a distance between the reticle masking blades and the pellicle membrane is too large to provide an effective shielding function. Although in use there is typically not a large amount of space between the pellicle membrane and other components (for example the reticle masking blades) it is thought that there is sufficient space for a relatively thin shield, allowing the pellicle according to the sixth aspect of the present disclosure to be used in existing lithographic apparatus.

The shield may extend past the border of the pellicle but remain outside the quality area (or a portion of the pellicle that corresponds to an image formation region of the reticle).

The pellicle according to the sixth aspect of the present disclosure may comprise any of the features of the pellicle according to the fourth aspect of the present disclosure as desired.

The shield may comprise a first shield member adjacent to a first surface of the peripheral portion of the membrane and second shield member adjacent to a second surface of the peripheral portion of the membrane.

The first surface may be a surface of the pellicle that, in use, faces away from the reticle (and may be referred to as an upper or front surface of the pellicle). The second surface may be a surface of the pellicle that, in use, faces towards the reticle (and may be referred to as a lower or rear surface of the pellicle).

It may be desirable for the shield to be as close to the surface of the membrane as possible, since this will minimize the amount of plasma diffusing under the shield (i.e. between the shield and the membrane), maximizing the plasma shielding. In general, it may be desirable for a distance between the shield and the surface of the membrane to be less than the Debye length of the plasma (which may be less than 1 mm or, during the EUV pulse, may be less than 0.2 mm). It may also be desirable for the shield to be far enough from the surface of the membrane to allow for any sag of the membrane without risk of the shield contacting the surface of the membrane.

It will be appreciated that for embodiments wherein the shield comprises a first shield member and a second shield member, the first shield member and the second shield member may be disposed at different distances from the membrane. Alternatively, the first shield member and the second shield member may be disposed at substantially the same distance from the membrane.

A distance between the shield and the membrane may be less than 1 mm. For example, a distance between the shield and the surface of the membrane may be between around 200 μm and 1000 μm. For example, a distance between the shield and the surface of the membrane may be between around 400 μm and 800 μm.

It will be appreciated that a distance between the first shield member and the membrane may be less than 1 mm and/or a distance between the second shield member and the membrane is less than 1 mm. In particular, a distance between the front surface of the membrane and the shield member adjacent thereto may be less than 1 mm.

The shield may have a thickness of less than 1 mm. The shield may have a thickness of between around 100 μm and 300 μm. The shield may have a thickness of around 200 μm or less. The thickness of the shield may be chosen to be something easily commercially available.

The shield may extend of the order of 1 mm to 1.5 mm away from the frame in a plane parallel to the membrane.

Preferably, the shield may extend to cover a portion of the membrane that, with no shield present, would be adjacent to the plasma in use but which does not receive EUV radiation. The shield may remain around 0.5 mm to 1.5 mm away from a quality area of the pellicle (i.e. a portion of the pellicle that corresponds to an image formation region of the reticle) so that the shield does not interfere with the EUV light cone.

The shield may be formed from a material that is transparent to a wavelength of radiation that, in use, is used to periodically heat the pellicle.

For example, the shield may be formed from a material that is transparent to infrared (IR) and/or deep ultra violet (DUV) radiation. This allows the shield to protect the pellicle from plasma while still allowing the membrane to be heated using such radiation periodically.

The shield may be formed from a material that is inert in hydrogen plasma.

The shield may comprise sapphire (Al₂O₃).

For example, the shield may comprise a sapphire (Al₂O₃) coated glass material. Alternatively, the shield may be formed from sapphire.

According to a seventh aspect of the present disclosure there is provided a lithographic apparatus comprising: a pellicle comprising: a frame; a membrane surrounded by, and supported by, the frame; and a shield adjacent to a peripheral portion of the membrane that is adjacent the frame; a source of hydrogen; and an illumination system arranged to illuminate the pellicle with radiation; wherein the shield is adjacent to a portion of the membrane that in the absence of such a shield an EUV-induced hydrogen plasma would diffuse to.

Advantageously, since the shield is adjacent to a portion of the membrane that in the absence of such a shield an EUV-induced hydrogen plasma would diffuse to the shield protects the membrane from the plasma (and associated plasma etching) that would be present in the absence of such a shield. The pellicle of lithographic apparatus according to the seventh aspect of the present disclosure may comprise a pellicle according to the fourth and/or sixth aspects of the present disclosure.

It will be appreciated that one or more aspects or features described above or referred to in the following description may be combined with one or more other aspects or features.

### BRIEF DESCRIPTION OF THE DRAWINGS

Embodiments of the invention will now be described, by way of example only, with reference to the accompanying schematic drawings, in which:

FIG. 1 is a schematic illustration of a lithographic system comprising a lithographic apparatus and a radiation source;

FIG. 2A is a schematic plan view of the support structure and patterning device shown in FIG. 1 disposed in a first end position;

FIG. 2B is a schematic plan view of the support structure and patterning device shown in FIG. 1 disposed in a second end position;

FIG. 3A is a schematic illustration of a first cross section through a patterning device on the support structure and reticle masking blades of the lithographic apparatus of FIG. 1;

FIG. 3B is a schematic illustration of a second cross section through a patterning device on the support structure and reticle masking blades of the lithographic apparatus of FIG. 1;

FIG. 4 is a plan view showing the y masking blades and the x masking blades (dotted lines) of the lithographic apparatus of FIG. 1 in a first configuration;

FIG. 5 shows an expected etching rate for hydrogen etching of carbon as a function of temperature for a hydrogen ion flux of 1.5·10¹⁹ m⁻²·s⁻¹ for four different ion energies: 5 eV, 10 eV, 20 e V and 30 eV; FIG. 5 also shows an sp3 carbon concentration as a function of temperature;

FIG. 6 is a schematic, qualitative graph of the hydrogen etch rate as a function of time following a period of heating to a temperature at which hydrogen etching becomes negligible, once the heating is removed;

FIG. 7 is schematic illustration of a new lithographic method according to an embodiment of the present disclosure;

FIG. 8 is a schematic plan view of a reticle and pellicle assembly 15 that may be used in the lithographic method of FIG. 7;

FIG. 9 shows a graph of a change in resist height on a wafer that has been exposed to EUV radiation via the pellicle as a function of non-scanning position (x position), which is indicative of the EUV transmission of a CNT pellicle as a function of non-scanning position (x position);

FIG. 10 shows a flow chart of a first embodiment of the method shown in FIG. 7;

FIG. 11A illustrates a standard lithographic method wherein a standard exposure field is used n*m times to form images on target regions on a substrate;

FIG. 11B illustrates the lithographic method shown in FIG. 10 wherein a standard exposure field is used n times to form images on target regions on a substrate, followed by an enlarged exposure field being used once; this process of n+1 exposures is repeated m times;

FIG. 12 shows a flow chart of a second embodiment of the method shown in FIG. 7;

FIG. 13 shows a graph of a change in resist height on a wafer that has been exposed to EUV radiation via the pellicle as a function of non-scanning position (x position) at the reticle level, which is indicative of the EUV transmission of a CNT pellicle as a function of non-scanning position (x position), for: (a) a standard lithographic method (solid line); (b) the new lithographic method of FIG. 12 wherein the masking blades are each stepped in 10 steps of 2 mm (dashed line);

FIG. 14 shows a flow chart of a third embodiment of the method shown in FIG. 7;

FIG. 15 is a schematic plan view representation of a (generally circular) substrate comprising a plurality of (generally rectangular) target regions or dies; also shown is a standard meander scan pattern in which each row of target regions (extending in a non-scanning direction) is exposed in turn, with the order of the exposure of the target regions indicated by a number on each target region, the scanning direction of the exposure of each target region is indicated by a solid arrow and the movement of the substrate in between exposure of two consecutive target regions C is indicated by dashed lines;

FIG. 16 shows a portion of a reticle and pellicle assembly in cross section comprising a reticle, a pellicle frame and a pellicle membrane, also shown is: one masking blade, a portion of the pellicle that can receive EUV radiation in use and a portion of the pellicle that does not receive EUV radiation in use but which does receive the hydrogen plasma;

FIG. 17A is a schematic cross section of a portion of a known pellicle;

FIGS. 17B to 17D are schematic cross sections of a portion of three new pellicles wherein along at least one edge of the membrane, an inner portion of the frame has a reduced thickness relative to an outer portion of the frame such that the inner portion of the frame is not in contact with the membrane;

FIG. 17E is a schematic cross section of a portion of another new pellicle which is a variant of the known pellicle shown in FIG. 17A but having has a smaller width than the known pellicle;

FIG. 18 shows a new reticle and pellicle assembly according to an embodiment of the present disclosure that comprises a new pellicle that is provided with a shield to protect a peripheral portion of the membrane from hydrogen plasma etching; and

FIG. 19 shows an enlarged portion of the new reticle and pellicle assembly shown in FIG. 18.

### DETAILED DESCRIPTION

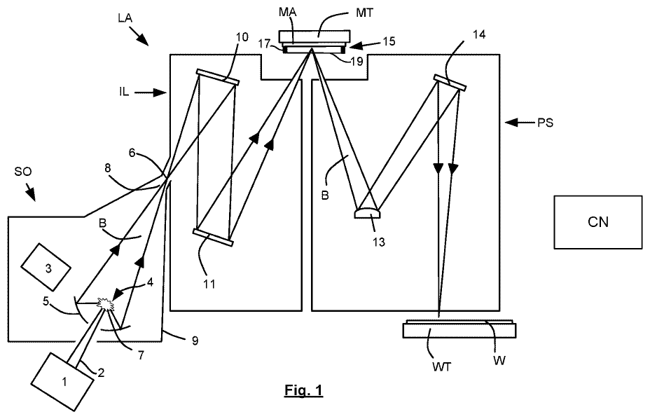

FIG. 1 shows a lithographic system. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a reticle assembly 15 including a patterning device MA (e.g., a reticle or mask), a projection system PS and a substrate table WT configured to support a substrate W. The illumination system IL is configured to condition the radiation beam B before it is incident upon the patterning device MA. The projection system is configured to project the radiation beam B (now patterned by the patterning device MA) onto the substrate W. The substrate W may include previously formed patterns. Where this is the case, the lithographic apparatus aligns the patterned radiation beam B with a pattern previously formed on the substrate W.

The radiation source SO, illumination system IL, and projection system PS may all be constructed and arranged such that they can be isolated from the external environment. A gas at a pressure below atmospheric pressure (e.g., hydrogen) may be provided in the radiation source SO. A vacuum may be provided in the illumination system IL and/or the projection system PS. A small amount of gas (e.g., hydrogen) at a pressure well below atmospheric pressure may be provided in the illumination system IL and/or the projection system PS.

The radiation source SO shown in FIG. 1 is of a type that may be referred to as a laser produced plasma (LPP) source. A laser 1, which may for example be a CO2 laser, is arranged to deposit energy via a laser beam 2 into a fuel, such as tin (Sn) that is provided from a fuel emitter 3. Although tin is referred to in the following description, any suitable fuel may be used. The fuel may for example be in liquid form, and may for example be a metal or alloy. The fuel emitter 3 may comprise a nozzle configured to direct tin, e.g., in the form of droplets, along a trajectory towards a plasma formation region 4. The laser beam 2 is incident upon the tin at the plasma formation region 4. The deposition of laser energy into the tin creates a plasma 7 at the plasma formation region 4. Radiation, including EUV radiation, is emitted from the plasma 7 during de-excitation and recombination of ions of the plasma.

The EUV radiation is collected and focused by a near normal incidence radiation collector 5 (sometimes referred to more generally as a normal incidence radiation collector). The collector 5 may have a multilayer structure that is arranged to reflect EUV radiation (e.g., EUV radiation having a desired wavelength such as 13.5 nm). The collector 5 may have an elliptical configuration, having two ellipse focal points. A first focal point may be at the plasma formation region 4, and a second focal point may be at an intermediate focus 6, as discussed below.

In other embodiments of a laser produced plasma (LPP) source the collector 5 may be a so-called grazing incidence collector that is configured to receive EUV radiation at grazing incidence angles and focus the EUV radiation at an intermediate focus. A grazing incidence collector may, for example, be a nested collector, comprising a plurality of grazing incidence reflectors. The grazing incidence reflectors may be disposed axially symmetrically around an optical axis.

The radiation source SO may include one or more contamination traps (not shown). For example, a contamination trap may be located between the plasma formation region 4 and the radiation collector 5. The contamination trap may for example be a rotating foil trap, or may be any other suitable form of contamination trap.

The laser 1 may be separated from the radiation source SO. Where this is the case, the laser beam 2 may be passed from the laser 1 to the radiation source SO with the aid of a beam delivery system (not shown) comprising, for example, suitable directing mirrors and/or a beam expander, and/or other optics. The laser 1 and the radiation source SO may together be considered to be a radiation system.

Radiation that is reflected by the collector 5 forms a radiation beam B. The radiation beam B is focused at point 6 to form an image of the plasma formation region 4, which acts as a virtual radiation source for the illumination system IL. The point 6 at which the radiation beam B is focused may be referred to as the intermediate focus. The radiation source SO is arranged such that the intermediate focus 6 is located at or near to an opening 8 in an enclosing structure 9 of the radiation source SO.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the reticle assembly 15 held by the support structure MT. The reticle assembly 15 includes a patterning device MA and a pellicle 19. The pellicle is mounted to the patterning device MA via a pellicle frame 17. The reticle assembly 15 may be referred to as a reticle and pellicle assembly 15. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 that are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system PS may include any number of mirrors (e.g., six mirrors).

The lithographic apparatus may, for example, be used in a scan mode, wherein the support structure (e.g., mask table) MT and the substrate table WT are scanned synchronously while a pattern imparted to the radiation beam is projected onto a substrate W (i.e., a dynamic exposure). The velocity and direction of the substrate table WT relative to the support structure (e.g., mask table) MT may be determined by the demagnification and image reversal characteristics of the projection system PS. The patterned radiation beam that is incident upon the substrate W may comprise a band of radiation. The band of radiation may be referred to as an exposure slit. During a scanning exposure, the movement of the substrate table WT and the support structure MT may be such that the exposure slit travels over an exposure field of the substrate W.

The radiation source SO and/or the lithographic apparatus that is shown in FIG. 1 may include components that are not illustrated. For example, a spectral filter may be provided in the radiation source SO. The spectral filter may be substantially transmissive for EUV radiation but substantially blocking for other wavelengths of radiation such as infrared radiation.

In other embodiments of a lithographic system the radiation source SO may take other forms. For example, in alternative embodiments the radiation source SO may comprise one or more free electron lasers. The one or more free electron lasers may be configured to emit EUV radiation that may be provided to one or more lithographic apparatus.

As was described briefly above, the reticle assembly 15 includes a pellicle 19 that is provided adjacent to the patterning device MA. The pellicle 19 is provided in the path of the radiation beam B such that radiation beam B passes through the pellicle 19 both as it approaches the patterning device MA from the illumination system IL and as it is reflected by the patterning device MA towards the projection system PS. The pellicle 19 comprises a thin film or membrane that is substantially transparent to EUV radiation (although it will absorb a small amount of EUV radiation). By EUV transparent pellicle or a film substantially transparent for EUV radiation herein is meant that the pellicle 19 is transmissive for at least 65% of the EUV radiation, preferably at least 80% and more preferably at least 90% of the EUV radiation. The pellicle 19 acts to protect the patterning device MA from particle contamination.

Whilst efforts may be made to maintain a clean environment inside the lithographic apparatus LA, particles may still be present inside the lithographic apparatus LA. In the absence of a pellicle 19, particles may be deposited onto the patterning device MA. Particles on the patterning device MA may disadvantageously affect the pattern that is imparted to the radiation beam B and therefore the pattern that is transferred to the substrate W. The pellicle 19 advantageously provides a barrier between the patterning device MA and the environment in the lithographic apparatus LA in order to prevent particles from being deposited on the patterning device MA.

The pellicle 19 is positioned at a distance from the patterning device MA that is sufficient that any particles that are incident upon the surface of the pellicle 19 are not in a field plane of the lithographic apparatus LA. This separation between the pellicle 19 and the patterning device MA acts to reduce the extent to which any particles on the surface of the pellicle 19 impart a pattern to the radiation beam B that is imaged onto the substrate W. It will be appreciated that where a particle is present in the beam of radiation B, but at a position that is not in a field plane of the beam of radiation B (for example not at the surface of the patterning device MA), then any image of the particle will not be in focus at the surface of the substrate W. In the absence of other considerations it may be desirable to position the pellicle 19 a considerable distance away from the patterning device MA. However, in practice the space which is available in the lithographic apparatus LA to accommodate the pellicle is limited due to the presence of other components. In some embodiments, the separation between the pellicle 19 and the patterning device MA may, for example, be approximately between 1 mm and 10 mm, for example between 1 mm and 5 mm, for example between 2 mm and 2.5 mm.

The pellicle may comprise a border portion and a membrane. The border portion of the pellicle may be hollow and generally rectangular and the membrane may be bounded by the border portion. As known in the art, the pellicle may be formed by deposition of one or more thin layers of material on a generally rectangular silicon substrate. The silicon substrate supports the one or more thin layers during this stage of the construction of the pellicle. Once a desired or target thickness and composition of layers has been applied, a central portion of the silicon substrate is removed by etching (this may be referred to as back etching). A peripheral portion of the rectangular silicon substrate is not etched (or alternatively is etched to a lesser extent than the central portion). This peripheral portion forms the border portion of the final pellicle while the one or more thin layers form the membrane of the pellicle (which is bordered by the border portion). The border portion of the pellicle may be formed from silicon.

Such a pellicle may require some support from a more rigid pellicle frame. The pellicle frame may provide two functions. First, the pellicle frame may support the pellicle and may also tension the pellicle membrane. Second, the pellicle frame may facilitate connection of the pellicle to a patterning device (reticle). It one known arrangement, the pellicle frame may comprise a main, generally rectangular body portion which is glued to the border portion of the pellicle and titanium attachment mechanisms that are glued to the side of this main body. Intermediate fixing members (known as studs) are affixed to the patterning device (reticle). The intermediate fixing members (studs) on the patterning device (reticle) may engage (for example releasably engage) with the attachment members of the pellicle frame.

One particularly promising material for use as a pellicle 19 membrane in an EUV lithographic apparatus is a fabric of carbon nanotubes (CNTs), which can provide very high EUV transmission (of >98%) and a very good mechanical stability. However, a low pressure hydrogen gas is typically provided within the lithographic apparatus LA, which forms a hydrogen plasma in the presence of the EUV radiation B (during exposure of the substrate W). It has been found that this hydrogen ions and hydrogen free radicals from the hydrogen plasma can etch pellicles 19 formed from CNTs, limiting the potential lifetime of the pellicle 19 and blocking commercial implementation of CNT pellicles.

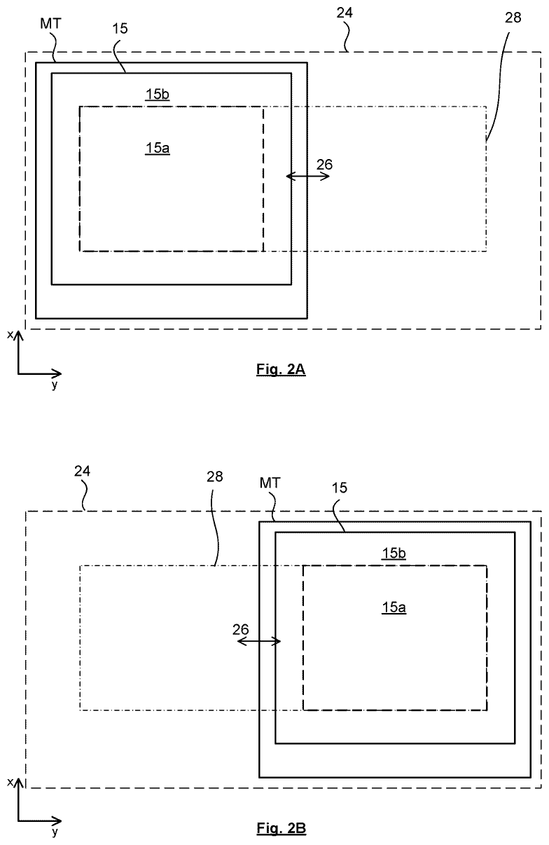

A description of some additional features of an example type of lithographic apparatus LA, in particular some features and components that are close to the support structure MT, is now provided with reference to FIGS. 2A to 4.

The support structure MT may be movable in a scanning direction so as to expose a greater region of the patterning device MA of the reticle and pellicle assembly 15 in a single dynamic scanning exposure, as now discussed with reference to FIGS. 2A and 2B. FIGS. 2A and 2B show a schematic plan view of the support structure MT and the reticle and pellicle assembly 15 in two different positions.

The support structure MT is movably mounted within a region 24. In particular, the support structure MT is movable in a scanning direction, as indicated by arrow 26, between a first end position (as shown in FIG. 2A) and a second end position (as shown in FIG. 2B).

Unless stated otherwise, throughout this specification, the following set of Cartesian co-ordinates will be used. The scanning direction is labelled as the y-direction. A direction which is also in the plane of the support structure MT and is perpendicular to the scanning direction is referred to as the non-scanning direction and is labelled as the x-direction. A direction which is perpendicular to the plane of the support structure MT is labelled as the z-direction.

The lithographic apparatus LA may be considered to comprise a scanning module operable to move the support structure MT in the scanning direction between at least the first end position and the second end position. For example, the scanning module may be operable to move the support structure MT in the scanning direction relative to a supporting frame (indicated schematically by region 24), which the support structure MT may be considered to be movably mounted to.

The reticle and pellicle assembly 15 may be considered to comprise a central portion 15a and a peripheral portion 15b surrounding the central portion 15a. The central portion 15a may be referred to as an image formation portion and may coincide with a portion the reticle MA that patterns the radiation beam B and a membrane of the pellicle 19. The peripheral portion 15b may coincide with a border portion of the pellicle 19 and a frame of the pellicle 19.

The movement of the support structure MT between the first and second positions defines an extended first portion region 28 of the support structure MT defined by all of the regions that the central portion 15a of the reticle and pellicle assembly 15 can be disposed in. That is, the extended first portion region 28 of the support structure MT is a region defined by moving the central portion 15a of the reticle and pellicle assembly 15 from the first end position (as shown in FIG. 2A) to the second end position (as shown in FIG. 2B).

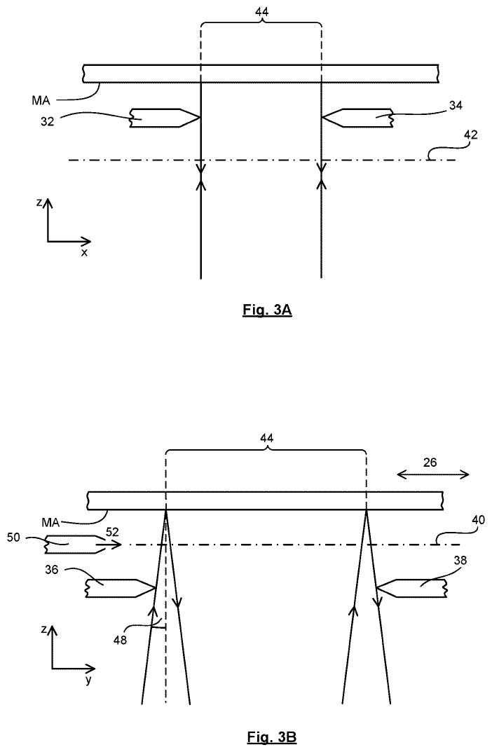

The lithographic apparatus LA is provided with four reticle masking blades, which define the extent of the field on the substrate W which is illuminated, as now described with reference to FIGS. 3A, 3B and 4. The illumination system IL is operable to illuminate a region of the patterning device MA when disposed on the support structure MT. This region may be referred to as the slit of the illumination system IL and is at least partially defined by four reticle masking blades, which define a generally rectangular region of the patterning device which can receive radiation. The extent of the generally rectangular region in a first direction, which may be referred to as the x direction, is defined by a pair of x masking blades 32, 34. The extent of the generally rectangular region in a second direction, which may be referred to as the y direction, is defined by a pair of y masking blades 36, 38.

Each of the masking blades 32, 34, 36, 38 is disposed close to, but slightly out of the plane of the patterning device on the support structure MT. The x masking blades 32, 34 are disposed in a first plane 40 and the y masking blades 36, 38 are disposed in a second plane 42.

Each of the masking blades 32, 34, 36, 38 defines one edge of a rectangular field region 44 in the plane of the patterning device MA which can receive radiation. In practice the illumination system IL may only illuminate part of the rectangular field region 44. As shown in FIG. 4, the illumination system IL may be arranged to illuminate a curved slit region 46, which may coincide with a part of the rectangular field region 44 (depending on the positions of the y masking blades 36, 38).

The curved slit region 46 may be partially defined by optics within the illumination system IL and/or the projection system PS. In addition, the curved slit region 46 may be partially defined by a plurality of independently movable objects provided along one or both of the curved edges of the curved slit region 46. The plurality of independently movable objects may be referred to as unicom fingers. The plurality of independently movable objects may be provided at different x positions and may be movable in the y direction to control an overlap between each of the movable objects and the radiation beam B produced by the illumination system IL. Controlling the y positions of the movable members may control a shape (or at least an intensity distribution) of one or both of the curved edges of the curved slit region 46. The movable members may be used to minimize variations in a dose of radiation provided by the radiation beam B at different positions in the non-scanning direction (i.e. the x direction). In addition, the curved slit region 46 may be partially defined by physical aperture, for example an entrance aperture of the projection system PS.

Each of the masking blades 32, 34, 36, 38 may be independently movable between a retracted position wherein it is not disposed in the path of the radiation beam and an inserted position wherein it at least partially blocks the radiation beam projected onto the patterning device MA by the illumination system IL. By moving the masking blades 32, 34, 36, 38 into the path of the radiation beam, the radiation beam B can be truncated (in the x and/or y direction) thus limiting the extent of the field region 44 which receives radiation beam B.

The x-direction corresponds to the non-scanning direction of the lithographic apparatus LA and the y-direction corresponds to the scanning direction of the lithographic apparatus LA. The patterning device MA is movable in the y-direction through the field region 44 (as indicated by again by arrow 26) so as to expose a greater region of the patterning device MA in a single dynamic scanning exposure.

During a dynamic exposure of a target region of a substrate W the target region is moved through an exposure region in the plane of the substrate W, the exposure region being a portion of the substrate W that the exposure region 44 of the patterning device MA is imaged onto by projection system PS. As the target region of the substrate W moves into the exposure region, the first masking blade 36, 38 moves such that only the target region receives radiation (i.e. no parts of the substrate outside of the target region are exposed). At the start of the scanning exposure one of the y masking blades 36, 38 is disposed in the path of the radiation beam B, acting as a shutter, such that no part of the substrate W receives radiation. At the end of the scanning exposure the other y masking blade 36, 38 is disposed in the path of the radiation beam B, acting as a shutter, such that no part of the substrate W receives radiation. During a middle part of the scanning exposure, when there is no overlap between the exposure region 44 (which receives the radiation B) and either of the adjacent target regions of the substrate W, both of the y masking blades 36, 38 are disposed in retracted positions.

Rays of radiation beam B are shown adjacent to each of the masking blades 32, 34, 36, 38. It will be appreciated that each point in the slit region 46 is illuminated with radiation from a range of angles. For example, each point in the slit region 46 may receive a cone of radiation. The rays of radiation beam B are shown adjacent to each of the masking blades 32, 34, 36, 38 indicate an average direction of the radiation received by the patterning device MA. The rays of radiation beam B are shown adjacent to each of the masking blades 32, 34, 36, 38 may be referred to as chief rays. As can be seen from FIGS. 3A and 3B, in this embodiment, as projected onto the x-z plane, a chief ray of the radiation is generally normally incident on the patterning device MA whereas as projected onto the y-z plane, a chief ray of the radiation is generally incident on the patterning device MA at an angle 48.

The lithographic apparatus LA may further comprise a gas nozzle 50, which may be arranged to direct a flow of gas 52 adjacent to the support structure MT. In particular, the flow of gas 52 provided adjacent to the support structure MT by the gas nozzle 50 may be generally parallel to a surface of the patterning device MA and may be referred to as a cross-flow. The gas nozzle 50 may be disposed generally in the same plane (the first plane 40) as the x masking blades 32, 34. The gas nozzle may point in the scanning direction such that the flow of gas 52 is generally parallel to the scanning direction and flows between the x masking blades 32, 34. The gas nozzle 50 may be considered to form part of a gas supply module which is operable to provide a flow of gas adjacent to the support structure MT.

The gas nozzle 50 may form part of a hydrogen supply operable to supply hydrogen in the vicinity of the pellicle 19 of the pellicle and reticle assembly 15 when supported by the support structure MT.

FIG. 4 shows a plan view of the y masking blades 36, 38 in the second plane 42 as viewed in the positive z-direction (i.e. upwards in FIG. 3B). The position of the x masking blades 32, 34 and the gas nozzle (which are disposed in the first plane 40) are shown in dotted lines. In FIG. 4, the four masking blades 32, 34, 36, 38 are disposed so as to define a generally rectangular field region 44, the slit region 46 being disposed within this generally rectangular field region 44. This may be a typical configuration of the four masking blades 32, 34, 36, 38 during the exposure of a central portion of a target region (for example a die on a substrate W). As explained above, each of the x masking blades 32, 34 is operable to move in the x direction and each of the y masking blades 36, 38 is operable to move in the y direction to control the size of the field region 44. The y masking blades 36, 38 are configured such that they can be actuated from the same side of the field region 44. To achieve this, the y masking blades 36, 38 are shaped such that (although they lie in substantially the same plane 42) each of the y masking blades 36, 38 is provided with one or more support portions which extend in the same direction (the negative y direction in FIG. 4).

The masking blades 32, 34, 36, 38 and the gas nozzle 50 may be mounted on a common masking blade assembly support (not shown). It will be appreciated that the masking blades 32, 34, 36, 38 may be movably mounted on such a support such that they can move relative thereto. The gas nozzle may be statically mounted on such a support.

In some embodiments, the lithographic apparatus LA may be provided with a pellicle 19 formed from CNTs.

The interaction of hydrogen ions with carbon materials is described quantitatively in the following two published papers, the contents of which are hereby incorporated by reference: (1) J. Roth, C. García-Rosales, “Analytic description of the chemical erosion of graphite by hydrogen ions”, Nucl. Fusion 1996, 36/12, 1647-1659; and (2) J. Roth, C. García-Rosales, “Corrigendum—Analytic description of the chemical erosion of graphite by hydrogen ions”, Nucl. Fusion 1997, 37, 897. This quantitative description of the interaction of hydrogen ions with carbon materials may be referred to as Roth-García-Rosales (RGR) model. The RGR model can be used to predict an etch yield of carbon materials as function of the temperature for the typical hydrogen ion energies encountered within the lithographic apparatus such as, for example, ion energies form 1-30 eV. Within an EUV lithographic apparatus a typical hydrogen ion flux incident on the pellicle may be of the order of 1·10¹⁹ m⁻²·s⁻¹. Within an EUV lithographic apparatus a typical hydrogen ion flux incident on the pellicle may be within a couple of orders of magnitude of 1·10¹⁹ m⁻²·s⁻¹ (for example from 10¹⁸ m⁻²·s⁻¹ to 10²⁰ m⁻²·s⁻¹).

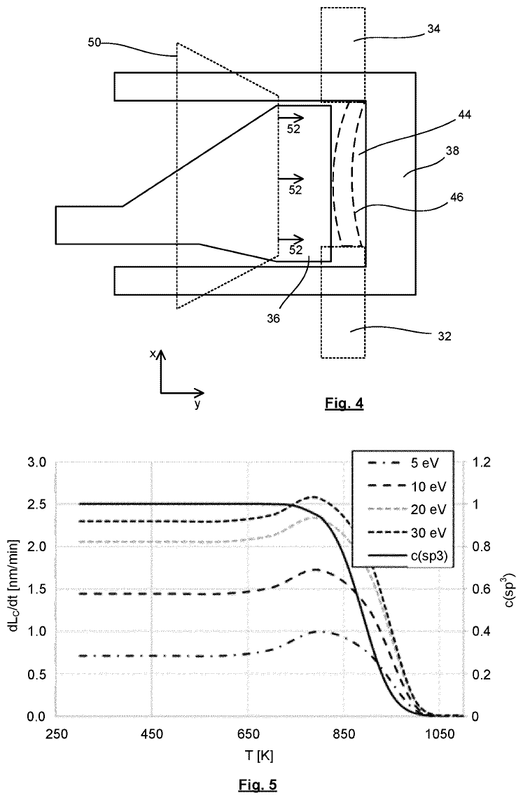

FIG. 5 shows an expected etching rate for hydrogen etching of carbon as a function of temperature for a hydrogen ion flux of 1.5·10¹⁹ m⁻²·s⁻¹ for four different ion energies: 5 eV, 10 eV, 20 e V and 30 eV. FIG. 5 also shows an sp3 carbon concentration as a function of temperature. From FIG. 5, it can be seen that for these typical ambient conditions in the lithographic apparatus LA, it is expected that for a pellicle formed purely from CNTs the hydrogen etching rate of the pellicle falls to a negligible level at a temperature of around 1050 K. However, it will be appreciated by the skilled person that under different conditions a different minimum temperature may be desirable.

In some embodiments, the minimum temperature is a temperature above which a hydrogen etching rate of the pellicle 19 falls to a negligible level. In some embodiments, the minimum temperature may be 1000 K or above. As explained above, this may be beneficial for a pellicle formed purely from CNTs wherein there is hydrogen ion flux incident on the pellicle may be of the order of 1·10¹⁹ m⁻²·s⁻¹ and the hydrogen ion energies are of the order of 1-30 eV. More preferably, the minimum temperature may be 1050 K or above. In some embodiments, the minimum temperature may be 1100 K or above.

The reduction of hydrogen etch rates to negligible levels at high temperatures may be governed by the transformation of sp3 carbon into sp2 carbon at a given temperature (see FIG. 5). Furthermore, a similar process occurs when forming sp2 carbon structures such as graphene or CNTs, wherein a temperature of carbon is raised to transform it into sp2 carbon from which the sp2 carbon structures are formed. Such processes for growing graphene include, for example chemical vapor deposition (CVD) and plasma-enhanced chemical vapor deposition (PE-CVD). Furthermore, it is known that growth of graphene from sp3 carbon sources can be initiated at temperatures as low as 300° C. (573 K) in the presence of single atoms catalyst. That is, conversion of sp3 carbon into sp 2 carbon can be initiated at this temperature in the presence of single atoms of catalyst. Lowering the etch-free operating temperature range for the pellicle 19 is beneficial since it reduces the heat load to the environment of the pellicle 19. It also means that less heat has to be supplied to the pellicle 19 by the heating system 20, which may ease the systems providing this heat.

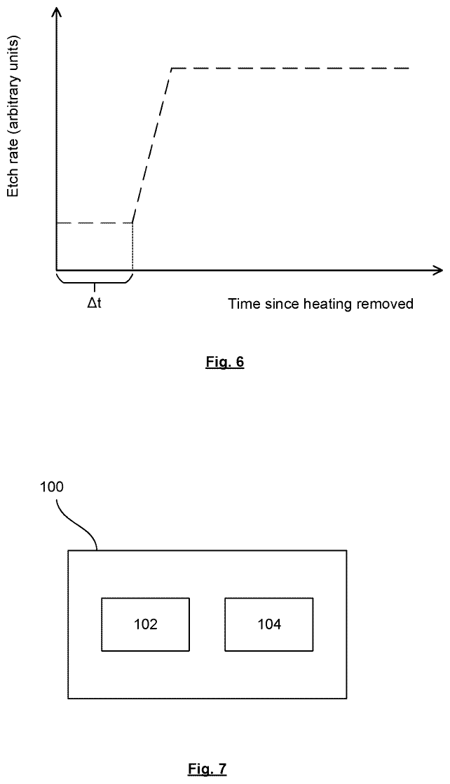

It has been found that once the pellicle 19 has been heated to above a threshold level (at which hydrogen etching becomes negligible), once the heating is removed, there is a time delay before the etching rate increases from the negligible level. It is has been found that, following a period of heating to a temperature at which hydrogen etching becomes negligible, once the heating is removed the hydrogen etch rate change over time generally as shown qualitatively in FIG. 6.

It is thought that heating to a sufficient temperature causes desorption of hydrogen from the pellicle 19, which reduces the hydrogen etching rate to negligible levels. Furthermore, it is thought that there is a time delay At in the increase in the etching rate after removal of the heating as it takes a non-zero time for the surfaces of the pellicle 19 to be replenished with hydrogen following the heating. This hydrogen replenishing rate may be proportional to the hydrogen radical flux to the membrane of the pellicle 19 within the lithographic apparatus LA. As the time since removal of the heating increases, eventually the etch rate rises to a typical value for a room temperature pellicle 19.

Some embodiments of the present disclosure relate to new lithographic methods 100, as shown schematically in FIG. 7. FIG. 8 is a schematic plan view of a reticle and pellicle assembly 15 that may be used in the lithographic method 100. The new lithographic methods 100 are now discussed with reference to FIGS. 7 and 8. It will be appreciated that the new lithographic methods 100 may be performed using a lithographic apparatus LA of the type described above with reference to FIGS. 1 to 4 and features of such a lithographic apparatus LA described above that are relevant to the new lithographic methods 100 will have the same reference numerals as those used in the description of FIGS. 1 to 4 above.

The lithographic methods 100 comprise steps 102 of forming an image of a reticle on a substrate a plurality of times. Each such image formation process comprises: illuminating a first portion 60 of a reticle and pellicle assembly 15 with a radiation beam B; and collecting radiation scattered by the reticle MA and projecting it onto a target region of a substrate W using projection optics PS.

The lithographic methods 100 further comprise the step 104 of periodically illuminating a second portion 62 of the reticle and pellicle assembly 15 with a radiation beam B. The second portion 62 of the reticle and pellicle assembly 15 at least partially surrounds the first portion 60. As shown in FIG. 8, in at least some embodiments, the second portion 62 of the reticle and pellicle assembly 15 substantially surrounds the first portion 60.

The first portion 60 of the reticle and pellicle assembly 15 may correspond to the central portion 15a shown in FIGS. 2A and 2B and described above. Similarly, the second portion 62 may correspond to at least a portion of the peripheral portion 15b shown in FIGS. 2A and 2B and described above. As shown in FIG. 8, in at least some embodiments, the reticle and pellicle assembly 15 may further comprise a third portion 64 surrounding the second portion 62. For such embodiments the peripheral portion 15b shown in FIGS. 2A and 2B and described above may be equivalent to the combination of the second and third portions 62, 64. The third portion 64 may, for example, coincide with a border portion of the pellicle 19 and a frame of the pellicle 19.

The lithographic method 100 shown schematically in FIG. 7 is advantageous, as now discussed.

As described above, any contamination on the reticle MA will, in general, alter the image formed on the substrate W, leading to printing errors. To avoid particle contamination of reticles MA, it is known to use a thin membranes, known as a pellicle 19, to protect the reticle MA. The pellicle 19 is disposed in front of the reticle MA and prevents particles from landing on the reticle MA. The pellicle 19 is disposed such that it is not sharply imaged onto the substrate W (e.g. a resist-coated wafer) and therefore particles on the pellicle 19 are less likely to interfere with the imaging process than particles on the reticle MA would be. One particularly promising material for use as a pellicle membrane in an EUV lithographic apparatus is a fabric of carbon nanotubes (CNTs), which can provide very high EUV transmission (of >98%) and a very good mechanical stability. However, a low pressure hydrogen gas is typically provided within the lithographic apparatus LA, which forms a hydrogen plasma in the presence of the EUV radiation (during exposure). It has been found that this hydrogen ions and hydrogen free radicals from the hydrogen plasma can etch pellicles 19 formed from CNTs, limiting the potential lifetime of the pellicle 19 and blocking commercial implementation of CNT pellicles.

It has been found that the etching of carbon by hydrogen ions and free radicals is temperature dependent. In particular, it has been found that: (a) the carbon etching rate is non-zero at lower temperatures; and (b) the carbon etching rate falls to a negligible level at a threshold temperature, above which the carbon etching remains at a negligible level. It has also been found that once a pellicle 19 has been heated to above a threshold level (at which hydrogen etching becomes negligible), once the heating is removed, there is a time delay before the etching rate increases from the negligible level.

The first portion 60 of the reticle and pellicle assembly 15 is the part that is illuminated (EUV) radiation B to form an image of the reticle MA on the substrate W. Therefore, the first portion 60 of the reticle and pellicle assembly 15 may comprise an image formation portion of the reticle MA and a corresponding portion of the pellicle 19. The first portion 60 of the reticle and pellicle assembly 15 is exposed to EUV radiation B during each image formation process 102. This will result in heating of the first portion 60 of the reticle and pellicle assembly 15 (for a lithographic scanner LA, each part of the first portion 60 of the reticle and pellicle assembly 15 will be heated periodically, with a periodicity given by the rate at which images are formed, i.e. once per die). As will be appreciated by the skilled person, within a lithographic apparatus LA, the hydrogen plasma is formed by the EUV radiation B (used for exposure of the substrate W). Therefore, the hydrogen plasma is formed in the vicinity of the first portion 60 of the reticle and pellicle assembly 15, which is exposed to EUV radiation and which is heated by the EUV radiation B. It will be further appreciated that the plasma may extend to surrounding regions, which are not heated directly by the EUV radiation B. As a result, the inventors have found that pellicles 19 tend to fail in a region 62 surrounding a central portion 60 (that corresponds to the image formation portion).

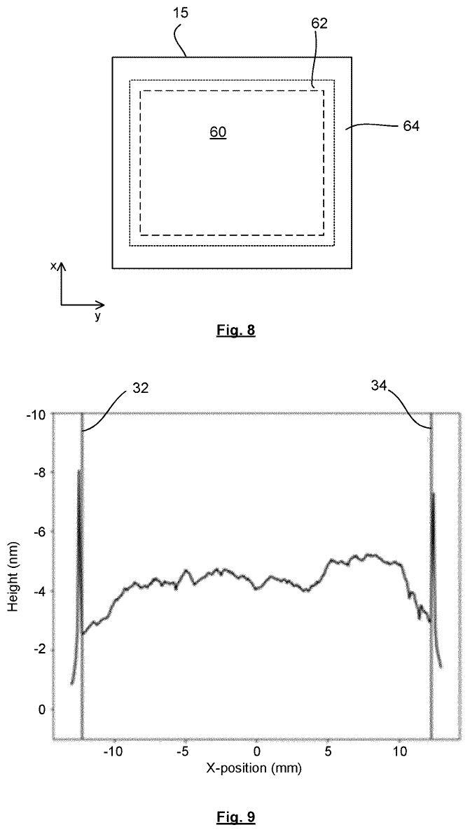

FIG. 9 shows a graph which is indicative of the EUV transmission of a CNT pellicle as a function of non-scanning position (x position). The graph shown in FIG. 9 is of a change in resist height on a wafer that has been exposed to EUV radiation via the pellicle as a function of non-scanning position (x position). The change in resist height on the wafer is proportional to a change in the EUV transmission of the pellicle. A larger negative change in resist height corresponds to a larger increase in EUV transmission. Also shown in FIG. 9 are the positions of the x masking blades 32, 34 (see FIGS. 3A and 3B). The portion of the graph shown in FIG. 9 between the two lines that correspond to the positions of the x masking blades 32, 34 is a first portion 60 of the reticle and pellicle assembly 15, which corresponds to the image formation portion of the reticle MA. It can be seen that there is sharp rise in the EUV transmission of the pellicle in the region just outside the two lines that correspond to the positions of the x masking blades 32, 34. This corresponds to a region which is not directly heated by the EUV radiation beam B but into which hydrogen ions and free radicals from the plasma can freely diffuse. This region, which may have a dimension of the order of 50 um or 100 um is adjacent to the first portion 60 of the reticle and pellicle assembly 15 and corresponds to the second portion 62 of the reticle and pellicle assembly 15.

Advantageously, by periodically illuminating a second portion 62 of the reticle and pellicle assembly 15 with a radiation beam B, hydrogen etching of the second portion 62 of the reticle and pellicle assembly 15 (which at least partially surrounds the first portion 60) can be suppressed.

The lithographic method 100 shown in FIG. 7 comprises both: (a) steps 102 of forming an image of a reticle on a substrate a plurality of times; and (b) a step 104 of periodically illuminating a second portion 62 of the reticle and pellicle assembly 15 with a radiation beam B. These steps may be performed in any order, as will be discussed below with reference to FIGS. 10 to 15.

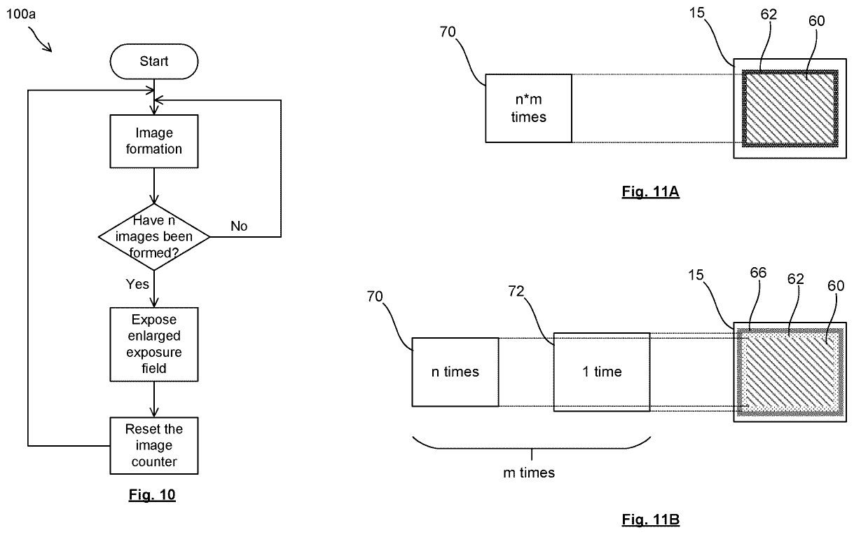

In some embodiments, the illumination 104 of the second portion 62 of the reticle and pellicle assembly 15 with a radiation beam B may occur in between exposure 102 of two target regions of a substrate W (i.e. in between two image formation processes using the first portion 60 of the reticle and pellicle assembly 15 with a radiation beam B). For example, the illumination 104 of the second portion 62 of the reticle and pellicle assembly 15 with a radiation beam B may occur may occur in between exposures of different target regions (or dies) of a single substrate W or even in between exposures of different substrates W. Examples of such arrangements will be discussed below with reference to FIGS. 10, 11A and 11B.

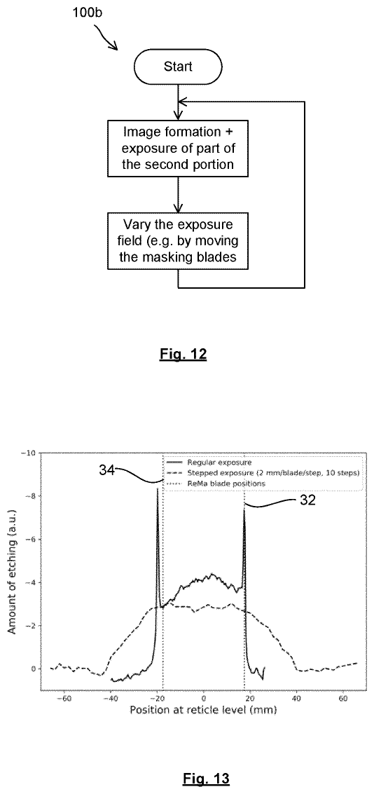

Alternatively, in some embodiments, the illumination 104 of the second portion 62 of the reticle and pellicle assembly 15 with a radiation beam B may occur during, and may be part of, the exposure of a target region of the substrate W (i.e. part of an image formation process using the first portion 60 of the reticle and pellicle assembly 15 with a radiation beam B). Examples of such arrangements will be discussed below with reference to FIGS. 12 to 15.

In some embodiments, substantially the entire second portion 62 of the reticle and pellicle assembly 15 may be illuminated with a radiation beam B at the same time. Examples of such arrangements will be discussed below with reference to FIGS. 10, 11A and 11B.

Alternatively, in some embodiments, the second portion 62 of the reticle and pellicle assembly 15 may be illuminated with a radiation beam B over a plurality of different exposures, each of which may expose a different part of the second portion 62 of the reticle and pellicle assembly 15 to radiation B. Examples of such arrangements will be discussed below with reference to FIGS. 12 to 15.

In some embodiments, the step 104 of periodically illuminating the second portion 62 of the reticle and pellicle assembly 15 with a radiation beam B is achieved by periodically illuminating an enlarged exposure field, as now discussed with reference to FIGS. 10 and 11.

The exposure field is a region of the reticle and pellicle assembly 15 that is exposed to radiation. It will be appreciated that an extent of the exposure field in a non-scanning direction (x-direction) may be defined by an extent of the radiation beam B in the non-scanning direction (which may be defined by a pair of masking blades 32, 34). It will be appreciated that an extent of the exposure field in a scanning direction (y-direction) may be defined by both an extent of the radiation beam in the scanning direction (which may be defined by a pair of masking blades 36, 38) and an extent of the scanning motion.

The illumination of such an enlarged field may be part of the exposure of a target region of the substrate W (i.e. part of an image formation process 102).

Alternatively, as now explained with reference to FIGS. 10 and 11, the illumination of an enlarged field may be in between exposure of two target regions of a substrate W (i.e. in between two image formation processes). For example, the illumination of an enlarged field may occur in between exposures of different target regions (or dies) of a single substrate W or even in between exposures of different substrates W.

FIG. 10 shows a flow chart of a first embodiment 100a of the method 100 shown in FIG. 7. Once the process starts, a plurality (n) of images are formed on a target region (e.g. a die) of a substrate W (e.g. a resist-coated wafer). After the formation of each image on a target region, if n images have not yet been formed then another image is formed. After the formation of each image on a target region, if n images have been formed then an enlarged exposure field is formed. It will be appreciated that the exposure of the enlarged field is achieved by appropriate control of the masking blades 32, 34, 36, 38. For example, the masking blades 32, 34, 36, 38 may be disposed in nominal positions during the formation of each image on a target region of the substrate W whereas the masking blades 32, 34, 36, 38 may be disposed in different positions during exposure of the enlarged field.

Once the enlarged field has been exposed to the EUV radiation beam B, an image counter may be reset and the exposure of another n images are formed on a target region (e.g. a die) of a substrate W (e.g. a resist-coated wafer). The process of n images being formed on target regions of a substrate W followed by 1 enlarged exposure of the reticle and pellicle assembly 15 may be repeated, for example, m times.

FIGS. 11A and 11B are a schematic illustration of a comparison between the method 100a shown in FIG. 10 and a standard lithographic process.

FIG. 11A illustrates a standard lithographic method wherein a standard exposure field 70 is used n*m times to form images on target regions on a substrate. A first portion 60 of the reticle and pellicle assembly 15 is exposed to the EUV radiation and therefore is periodically heated to a sufficient temperature that hydrogen etching of the first portion 60 is minimal. The hydrogen plasma formed by the EUV radiation in the vicinity of the first portion 60 of the reticle and pellicle assembly 15 will also diffuse to a region adjacent a second portion 62 of the reticle and pellicle assembly 15 surrounding the first portion 60. Since the second portion 62 of the reticle and pellicle assembly 15 is not heated directly by the EUV radiation B, this second portion 62 of the reticle and pellicle assembly 15 will be subject to significant hydrogen etching and the pellicle will tend to fail in this second portion 62.

FIG. 11B illustrates the lithographic method 100a shown in FIG. 10 wherein a standard exposure field 70 is used n times to form images on target regions on a substrate W, followed by an enlarged exposure field 72 being used once. This process of n+1 exposures is repeated m times. The first portion 60 of the reticle and pellicle assembly 15 is exposed to the EUV radiation and therefore is again periodically heated to a sufficient temperature that hydrogen etching of the first portion 60 is minimal. During the n exposures using the standard exposure field, the hydrogen plasma formed by the EUV radiation in the vicinity of the first portion 60 of the reticle and pellicle assembly 15 will also diffuse to a region adjacent a second portion 62 of the reticle and pellicle assembly 15 surrounding the first portion 60. However, since the second portion 62 of the reticle and pellicle assembly 15 is heated directly by the EUV radiation B during the exposure using the enlarged exposure field, this second portion 62 of the reticle and pellicle assembly 15 will be subject to significantly less hydrogen etching. In fact, if a time period between two consecutive illuminations of the second portion 62 of the reticle and pellicle assembly 15 with a radiation beam B using the enlarged exposure field 72 is sufficiently small so as to not allow a surface of the pellicle to become replenished with hydrogen following the heating from the first such illumination then hydrogen etching of the second portion 62 may be minimal. Again, it will be appreciated that the time required for the surface of the pellicle to become replenished with hydrogen following the heating from the first illumination with the enlarged field 72 will be dependent on conditions in the vicinity of the pellicle. In some embodiments, a time period between two consecutive illuminations of the second portion 62 of the reticle and pellicle assembly may be of the order of 100 ms or less.

During the exposures using the enlarged exposure field 72, the hydrogen plasma formed by the EUV radiation B in the vicinity of the first and second portions 60, 62 of the reticle and pellicle assembly 15 will also diffuse to a region adjacent a third portion 66 of the reticle and pellicle assembly 15 surrounding the second portion 62. Since the third portion 66 of the reticle and pellicle assembly 15 is not heated directly by the EUV radiation B, this third portion 66 of the reticle and pellicle assembly 15 will be subject to significant hydrogen etching and the pellicle may tend to fail in this third portion 66. However, the third portion 66 of the reticle and pellicle assembly 15 will only be subject to this plasma for 1/(n+1)th of the time. This is in contrast to the standard lithographic method in which the second portion 62 of the reticle and pellicle assembly 15 is exposed to the plasma for substantially the entire time. Therefore, there will be a reduction in the amount of etching in the region that experiences the most etching and a corresponding increase in the lifetime of the pellicle (by a factor of n+1).

When the enlarged exposure field 72 is periodically illuminated with radiation B, it may be that the radiation scattered from the reticle and pellicle assembly 15 is not projected onto the substrate W. Such an exposure may be referred to as a dummy exposure.

Such a dummy exposure may result in the least adaptation of standard lithographic methods. However, such a dummy exposure also results in a reduction in productivity or throughput of the lithographic apparatus LA. In some embodiments, an additional dummy exposure may be used approximately once per wafer (of the order of ~100 full field dies). This means the throughput slowdown of the dummy exposure site is only ~1%. In some embodiments, a dummy exposure may be performed approximately every 10 dies, resulting in a throughput slowdown of the dummy exposure of ~10%.

In some embodiments, the substrate W may be moved such that the radiation scattered from the reticle and pellicle assembly 15 is not incident on the substrate W. The dummy exposure can simply be chosen outside the wafer W area, and exposed after a row of target regions on the wafer W. Such exposures are already used in some lithographic methods on order to guarantee edge dies are exposed to the same stray light as dies in the middle of the wafer W. Alternatively, in some embodiments, a shutter may be closed so as to prevent the radiation scattered from the reticle and pellicle assembly 15 from being incident on the substrate W.

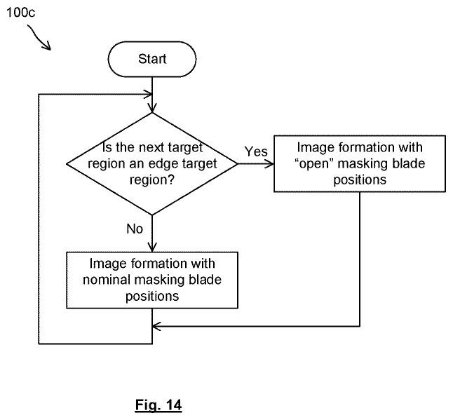

In some embodiments of the embodiment 100a shown in FIGS. 10, 11A and 11B, the illumination of such an enlarged field 72 may be part of the exposure of a target region of the substrate W (i.e. part of an image formation process 102). Advantageously, this would mean that the enlarged field 72 exposures would not negatively affect the productivity of the lithographic apparatus LA. Such embodiments may be achieved by making some changes to the reticle and/or the field distribution on the wafer W (as discussed further below with reference to FIGS. 14 and 15).

In some embodiments of the method 100 shown in FIG. 7, the step 104 of periodically illuminating the second portion 62 of the reticle and pellicle assembly 15 with a radiation beam is achieved by varying the exposure field. It will be appreciated that, in general, an extent and/or position of the exposure field may be varied. The embodiment 100a described above with reference to FIGS. 10 to 11B is an example of such an embodiment in which the exposure field is varied. Further embodiments of such methods in which the exposure field is varied are now described with reference to FIGS. 12 to 15.

FIG. 12 shows a flow chart of a second embodiment 100b of the method 100 shown in FIG. 7. Once the process starts, a plurality of images are formed on a target region (e.g. a die) of a substrate W (e.g. a resist-coated wafer). After the formation of each image on a target region, the exposure field is varied (in extent and/or position). It will be appreciated that varying the exposure field is achieved by appropriate control of the masking blades 32, 34, 36, 38.

For example, the masking blades 32, 34, 36, 38 may be disposed in first positions during the formation of a first image on a target region of the substrate W whereas the masking blades 32, 34, 36, 38 may be disposed in second positions during formation of a second image on a target region of the substrate W and so on. In general, a position of at least one edge of the exposure field (defined by one of the masking blades 32, 34, 36) for at least some image formation processes is shifted by an offset relative to position of that at least one edge of the exposure field in the previous image formation process.

For example, the offset may be of the order of 50 um. At least one of the edges of the exposure field may be stepped by such an offset every n exposure processes (for example every exposure process). In some embodiments all edges of the exposure field may be stepped by such an offset (by stepping each of the masking blades 32, 34, 36, 38 by such an offset). The method 100b may use, for example, of the order of 5 different positions for each edge of the exposure field and the positions of each edge of the exposure field may be stepped or cycled through all of the (for example 5) different positions.

FIG. 13 shows a graph that is indicative of the EUV transmission of a CNT pellicle as a function of non-scanning position (x position) for: (a) a standard lithographic method (solid line); (b) an embodiment 100b of the new method wherein the masking blades 32, 34 are each stepped in 10 steps of 2 mm (dashed line). The graph shown in FIG. 13 is of a change in resist height on a wafer that has been exposed to EUV radiation via the pellicle as a function of non-scanning position (x position) at the reticle level. The change in resist height on the wafer is proportional to a change in the EUV transmission of the pellicle. A larger negative change in resist height corresponds to a larger increase in EUV transmission. Also shown in FIG. 13 are the approximate positions of the x masking blades 32, 34 (see FIGS. 3A and 3B). From a comparison of the curve for the standard lithographic method and the embodiment 100b of the new method it can be seen that, advantageously, the sharp peak in the EUV transmission of the pellicle in the region just outside the x masking blades 32, 34 is no longer present due to the stepping of the masking blades 32, 34.

In an alternative embodiment, the exposure field for the plurality of image formation processes may be continuously varying. For example, a position of at least one edge of the exposure field (as defined by the masking blades 32, 34, 36, 38) may be continuously varying. For example, a position of at least one edge of the exposure field (as defined by the masking blades 32, 34, 36, 38) may oscillate over a range of positions about a nominal position. An amplitude of such oscillation may be of the order of 100 μm. In some embodiments all edges of the exposure field may be continuously varying (by oscillating the positions of all of the masking blades 32, 34, 36, 38).

Although the example embodiment 100b shown in FIG. 12 comprises varying the exposure field after image formation process, in alternative embodiments the exposure field may be varied after a different number of image formation process. In general, the exposure field for at least some image formation processes may be different to the exposure field for a previous image formation process.

In some embodiments, for the formation of an image on each target region of a substrate W that is adjacent to an edge of the substrate W at least one of the masking blades 32, 34, 36, 38 that corresponds to an edge of the exposure field that is adjacent the edge of the substrate W may be positioned so as to enlarge the exposure field, as now described with reference to FIGS. 14 and 15. As explained above, in general, four masking blades 32, 34, 36, 38 may be used during the exposure of each target region of a substrate W so as to define the exposure field.

FIG. 14 shows a flow chart of a third embodiment 100c of the method 100 shown in FIG. 7. FIG. 15 is a schematic plan view representation of a (generally circular) substrate W comprising a plurality of (generally rectangular) target regions C or dies. In the embodiment shown in FIG. 15 the substrate W comprises 110 target regions C. The target regions C that are adjacent to the edge of the substrate W may be referred to as edge target regions or edge dies. It will be appreciated that such edge target regions C do not have adjacent target regions C on all sides. Rather, on at least one side (adjacent the edge of the substrate W), each edge target region C has no adjacent neighbour target region C. For example, the top-left target region C (number 110) has no adjacent target region in the positive y direction or in the negative x direction. For such edge target regions C (or dies) on the substrate W, the masking blades 32, 34, 36, 38 may be positioned so as to enlarge the exposure region, as now explained.

Once the third embodiment 100c of the method 100 starts, a plurality of images are formed on a target region (e.g. a die) of a substrate W (e.g. a resist-coated wafer). If the next target region to be exposed is not an edge target region then a nominal exposure region may be used (for example with the masking blades 32, 34, 36, 38 in a nominal position). If the next target region to be exposed is an edge target region then an enlarged exposure region may be used (for example with at least one of the masking blades 32, 34, 36, 38 in an open position). It will be appreciated that varying the exposure field is achieved by appropriate control of the masking blades 32, 34, 36, 38.

For example, for such edge target regions C (or dies) on the substrate W, the masking blades 32, 34, 36, 38 may be shifted by 1 mm or more relative to a nominal position so as to enlarge the exposure region. Advantageously, this will result in illumination of a portion of the reticle and pellicle assembly 15 with a radiation beam B that is adjacent to the first portion 60 of the reticle and pellicle assembly 15 (and which corresponds to part of the second portion 62 of the reticle and pellicle assembly 15). If the masking blades 32, 34, 36, 38 are controlled in this way for all such edge dies C, a portion 62 of the reticle and pellicle assembly 15 that substantially surrounds the first portion 60 of the reticle and pellicle assembly 15 can be illuminated with radiation B.

Forming an image of a reticle MA on a substrate a plurality of times may comprise forming an image of the reticle MA on a plurality of target regions C of the substrate W. Each of the plurality of target regions C may be generally rectangular. The plurality of target regions C may be arranged as a two-dimensional array.

In some embodiments, the two-dimensional array of target regions C may be exposed using a standard meander scan pattern in which each row of target regions C (extending in a non-scanning direction) is exposed in turn. Such a standard meander scan pattern is illustrated in FIG. 15, with the order of the exposure of the target regions C indicated by a number on each target region. The scanning direction of the exposure of each target region C is indicated by a solid arrow and the movement of the substrate W in between exposure of two consecutive target regions C is indicated by dashed lines.

One target region C from each row has no adjacent target region on one side and another target region has no adjacent target region on the other side. For example in the second row from the top, target region 99 has no adjacent target region to the left (negative x-direction) and target region 106 has no adjacent target region to the right (negative y-direction). Therefore, with such an arrangement, portions of the reticle and pellicle assembly 15 that are adjacent to the first portion 60 of the reticle and pellicle assembly 15 but offset in the non-scanning direction (x-direction) can be exposed to radiation during exposure of each row.

In contrast, during exposure of the first half of the substrate W there are some target regions that have no adjacent target region on a first side in the scanning direction but there are no target regions that have no adjacent target region on the other (second) side in the scanning direction. For example, during exposure of the first half of the substrate W (the lower half of the substrate W in FIG. 15) there are some target regions C that have no adjacent target region below them (negative y-direction) but there are no target regions that have no adjacent target region above them (positive y-direction). Similarly, during exposure of the first half of the substrate there are some target regions that have no adjacent target region on the second side in the scanning direction but there are no target regions that have no adjacent target region on the first side in the scanning direction. For example, during exposure of the second half of the substrate W (the upper half of the substrate W in FIG. 15) there are some target regions C that have no adjacent target region above them (positive y-direction) but there are no target regions that have no adjacent target region below them (negative y-direction).

In some embodiments, the two-dimensional array of target regions C may be exposed using an exposure pattern in which the plurality of rows of target regions C (extending in a non-scanning direction, i.e. the x-direction) are exposed in a different order in order to increase the frequency with which target regions having no adjacent target region on the first or second side in the scanning direction (i.e. above or below them in FIG. 15) is increased. In some embodiments, forming an image of a reticle MA on a substrate W a plurality of times may comprise forming an image of the reticle MA on a plurality of target regions C of the substrate W, the plurality of target regions C arranged as a two-dimensional array, wherein the two-dimensional array of target regions C are exposed one row at a time and wherein the rows are not exposed in order.

In some embodiments of the method 100 shown in FIG. 7, during each image formation process at least one masking blade 32, 34, 36, 38 may be used so as to mask an adjacent target region C of the substrate W from the radiation beam B. Preferably, four masking blades 32, 34, 36, 38 may be used so as to define an exposure region and to mask adjacent target regions C on all four sides of the exposure region C. The exposure field C may be defined by an exposure region, a scanning length, and the positions of the four masking blades 32, 34, 36, 38.

In some embodiments of the method 100 shown in FIG. 7, at least one reticle masking blade 32, 34, 36, 38 may be manipulated such that a perimeter line of the exposure region is spread out over an extended area. For example, the perimeter line of the exposure region may be spread out over an area having a dimension of the order of 100 μm.

In some embodiments of the method 100 shown in FIG. 7, each image formation process may comprise a scanning exposure in which the reticle and pellicle assembly 15 is moved in a scanning direction (e.g. the y-direction) relative to the radiation beam B.

In general, a duration of the periodic illumination of the second portion 62 of the reticle and pellicle assembly 15 with a radiation beam B in embodiments of the method 100 shown in FIG. 7 may be sufficiently large to heat the second portion 62 of the pellicle to a desired temperature (for example above a threshold temperature above which hydrogen etching of the pellicle is negligible). In some embodiments, the desired temperature may be above 900 K. It will be appreciated that the time required for heating the pellicle to a desired temperature will be dependent on a power of the radiation beam B while it is heating the pellicle.

In some embodiments of the method 100 shown in FIG. 7, periodically illuminating a second portion 62 of the reticle and pellicle assembly 15 with a radiation beam B may comprise exposing the second portion 62 to EUV radiation to heat up the pellicle to a temperature at which a hydrogen etching rate of the pellicle is negligible. For example, periodically illuminating a second portion 62 of the reticle and pellicle assembly 15 with a radiation beam B may comprise exposing the second portion to EUV radiation to heat up the pellicle to a temperature above 800 K, for example a temperature above 900 K.

In general, a time period between two consecutive illuminations of the second portion 62 of the reticle and pellicle assembly 15 with a radiation beam B may be sufficiently small so as to not allow a surface of the pellicle to become replenished with hydrogen following the heating from the first illumination. Again, it will be appreciated that the time required for the surface of the pellicle to become replenished with hydrogen following the heating from the first illumination will be dependent on conditions in the vicinity of the pellicle. In some embodiments, a time period between two consecutive illuminations of the second portion of the reticle and pellicle assembly may be of the order of 100 ms.

In some embodiments of the method 100 shown in FIG. 7, the step 104 of periodically illuminating the second portion 62 of the reticle and pellicle assembly 15 with a radiation beam B is such that the second portion 62 of the reticle and pellicle assembly 15 is illuminated once per substrate W.

In some embodiments of the method 100 shown in FIG. 7, the step 104 of periodically illuminating the second portion 62 of the reticle and pellicle assembly 15 with a radiation beam B is such that the second portion 62 of the reticle and pellicle assembly 15 is illuminated once per each row of target regions C on a substrate W.

As described above, embodiments of the present disclosure proposes to use the masking blades 32, 34, 36, 38 in a novel operation mode. In some embodiments (especially when an enlarged exposure field is exposed as part of the formation of an image on a target region of a substrate W), this new functionality of the masking blades 32, 34, 36, 38 may be combined with some changes to the reticle layout and/or pellicle border, as now discussed.

Typically, a reticle comprises a central image formation portion, which is surrounded by a black border region. The black border region may have a reflectivity for EUV radiation in the range of 0.1% to 5%, for example less than 1%. The black border region may have a dimension of the order of 1-5 mm, for example of the order of 2-3 mm. Surrounding the black border the reticle may be provided with one or more alignment markers.

For embodiments wherein an enlarged exposure field is exposed as part of the formation of an image on a target region of a substrate W, the enlarged field may negatively impact critical dimension uniformity (CDU), especially at the corners of the target regions due to additional flare. This impact will depend on the effectiveness of the reticle black border and the used field layout on the wafer (for example how close two adjacent target regions C are together).

When using an enlarged exposure to recover the pellicle, the usable image area may be reduced. As the enlarged exposure field is not used for every exposure (of a target region C of the substrate W) the additional area (relative to the nominal exposure field) cannot contain imaging information. In some embodiments, the reticle may be provided with an enlarged black border in order to mitigate any loss of imaging performance caused by the enlarged exposure field.

For example, in some embodiments, the new masking blade 32, 34, 36, 38 operation may involve the periodic use of an enlarged exposure field, in which each of the masking blades 32, 34, 36, 38 moved outwards by a distance of the order of ~800 μm for a single die/target region C. As explained above with reference to FIGS. 10, 11A and 11B, this is done such that the second portion 62 of the reticle and pellicle assembly 15 is illuminated by EUV light, preventing hydrogen etching of this second portion 62 from starting. The frequency of this enlarged exposure region may be of the order of ~ 1/50 dies/target regions C, which will result in a lifetime extension of the pellicle of a fact of 50.

However, with some existing reticle layouts, the reticle black border is now sufficiently wide to allow the masking blades 32, 34, 36, 38 to be freely moved this far out without causing imaging artefacts on the edges and corners of the target regions C.

One way to achieve the enlarged black border may be to reduce an extent of the usable image formation area. For example, the imaging field may be reduced by moving all of the edges of the image formation region of the reticle inwards by ~800 μm (in both the x and y directions).

Another way to achieve the enlarged black border may be to move the location of alignment markers on the reticle. The alignment markers are typically disposed on a so-called quiet zone. The quiet zone is a region around the alignment markers where no other radiation scattering or reflective features are disposed which may disturb the signals from the alignment markers. In particular, no other radiation scattering or reflective features are disposed in the quiet zone so as to: (a) avoid cross terms to the alignment marker signals; (b) avoid any radiation leaking through the surrounding absorber material (typically the alignment markers can be significantly smaller than a sensitive area of the detector used for the alignment measurements so that these measurements are very sensitive to any stray radiation, even when falling on the absorber area of detector). In some embodiments, in order to achieve an enlarged black border, the alignment markers may be moved from the quiet zone and into the scribe lane (a region that corresponds to a gap between adjacent target regions C on the wafer W), which may allow the black border to be enlarged into the quiet zone. Alternatively, in some embodiments a dimension of the pellicle border and frame may be reduced, for example by 1 mm, a dimension of the black border can be increased by 1 mm, and the alignment markers can be moved outwards by 1 mm. For such embodiments, the alignment markers may end up on a lower-quality portion of the reticle. However, it is expected that this will not cause any significant problems.

If a reduction in usable image area is not acceptable or desirable an alternative may be to allow the enlarged exposure field to overlap with the pellicle border. Typically exposure on the pellicle border is avoided as all EUV light will be absorbed and this will result in a hot border, however, the heat load from the periodic use of an enlarged exposure field on the pellicle border may be acceptable.

Some embodiments of the present disclosure relate to lithographic apparatus LA of the type shown in FIG. 1. The lithographic apparatus LA may comprise of the features described above with reference to FIGS. 1 to 4. In particular, the new lithographic apparatus LA according to an embodiment of the present disclosure comprises: a controller CN (see FIG. 1) operable to control the illumination system IL, the support structure MT, the substrate table WT and the projection system PS so as to: (a) form an image of a reticle MA supported by the support structure MT on a substrate W a plurality of times, each such image formation process comprising: illuminating a first portion 60 of a reticle and pellicle assembly 15 with a radiation beam B; and projecting radiation scattered by the reticle MA onto a target region C of a substrate W using the projection optics PS; and (b) periodically illuminate a second portion 62 of the reticle and pellicle assembly 15 with the radiation beam B, the second portion 62 of the reticle and pellicle assembly 15 at least partially surrounding the first portion 60.

Such a lithographic apparatus LA is advantageous, as it allows for implementation of the new lithographic methods 100, 100a, 100b, 100c discussed above.

As discussed above, a pellicle 19 disposed in front of the reticle MA can prevent particles from landing on the reticle MA, which can improve optical performance (by reducing printing errors). One particularly promising material for use as a pellicle membrane in an EUV lithographic apparatus is a fabric of carbon nanotubes (CNTs), however, CNT pellicles are susceptible to hydrogen etching. It has been found that the etching of carbon by hydrogen ions and free radicals falls to a negligible level at a threshold temperature, above which the carbon etching remains at a negligible level. It has also been found that once a pellicle 19 has been heated to above a threshold level (at which hydrogen etching becomes negligible), once the heating is removed, there is a time delay before the etching rate increases from the negligible level.

The first portion 60 of a reticle and pellicle assembly 15 is the part that is illuminated by (EUV) radiation to form an image of the reticle MA on the substrate W. Therefore, the first portion 60 of the reticle and pellicle assembly 15 may comprise an image formation portion of the reticle MA and a corresponding portion of the pellicle 19. The first portion 60 of the reticle and pellicle assembly 15 is exposed to EUV radiation during each image formation process. This will result in heating of the first portion 60 of the reticle and pellicle assembly 15 (for a lithographic scanner LA, each part of the first portion 60 of the reticle and pellicle assembly 15 will be heated periodically, with a periodicity given by the rate at which images are formed, i.e. once per die). As will be appreciated by the skilled person, within a lithographic apparatus LA, the hydrogen plasma is formed by the EUV radiation (used for exposure of the substrate W). Therefore, the hydrogen plasma is formed in the vicinity of the first portion 60 of the reticle and pellicle assembly 15, which is exposed to EUV radiation and which is heated by the EUV radiation. It will be further appreciated that the plasma may extend to surrounding regions, which are not heated directly by the EUV radiation. As a result, the inventors have found that pellicles tend to fail in a region surrounding a central portion (that corresponds to the image formation portion).

Advantageously, by periodically illuminating a second portion 62 of the reticle and pellicle assembly 15 with a radiation beam B, hydrogen etching of the second portion 62 of the reticle and pellicle assembly 15 (which at least partially surrounds the first portion 60) can be suppressed.

The controller CN may be operable to implement the method of the new lithographic methods 100, 100a, 100b, 100c discussed above.

The lithographic apparatus LA may further comprising a scanning mechanism operable to move the support structure MT relative to the radiation beam B conditioned by the illumination system IL in a scanning direction (y-direction). The scanning mechanism may be further operable to move the substrate table WT relative to the projection system PS such that an image of a reticle MA formed by the projection system PS is substantially stationary with respect to the substrate W. This may be described as synchronized movement of the support structure MT and substrate table WT. The movement (direction and speed) of the substrate table WT relative to the support structure MT will, in general, be dependent on the image reversal and magnification properties of the projection system PS.

The controller CN may be operable to control the scanning mechanism.

As explained above, the lithographic apparatus LA may comprising: a first pair of masking blades 36, 38 arranged to define an extent of an exposure region in a first direction (y-direction); and a second pair of masking blades 32, 34 arranged to define an extent of an exposure region in a second direction (x-direction).

The first and second pair of masking blades 36, 38, 32, 34 may be movable so as to vary the extent of the exposure region. The controller CN may be operable to control a position of each of the first and second pair of masking blades 36, 38, 32, 34. In use, the two pairs of masking blades 36, 38, 32, 34 may be used so as to define the exposure region and to mask adjacent target regions C on all four sides of the exposure region.

In some embodiments, in order to form an image of a reticle MA supported by the support structure MT on target region C of a substrate W, the controller CN may be operable to: control the scanning mechanism so as to move a reticle MA supported by the support structure MT through an exposure region; and control a position of the first pair of masking blades 36, 38 so as to mask an adjacent target region C of the substrate W from the radiation beam.

In some embodiments, in order to illuminate the second portion 62 of the reticle and pellicle assembly 15 with the radiation beam B, the controller CN may be operable to control the first and/or second pair of masking blades 36, 38, 32, 34 so as to illuminate an enlarged exposure field.

The exposure field is a region of the reticle and pellicle assembly 15 that is exposed to radiation. It will be appreciated that an extent of the exposure field in a non-scanning direction (x-direction) may be defined by an extent of the radiation beam in the non-scanning direction (which may be defined by a pair of masking blades 32, 34). It will be appreciated that an extent of the exposure field in a scanning direction (y-direction) may be defined by both an extent of the radiation beam in the scanning direction (which may be defined by a pair of masking blades 36, 38) and an extent of the scanning motion.

The illumination of such an enlarged field may be part of the exposure of a target region C of the substrate W (i.e. part of an image formation process). Alternatively, the illumination of an enlarged field may be in between exposure of two target regions C of a substrate W (i.e. in between two image formation processes). For example, the illumination of an enlarged field may occur in between exposures of different target regions C (or dies) of a single substrate W or even in between exposures of different substrates W.

In some embodiments, in order to illuminate the second portion 62 of the reticle and pellicle assembly 15 with the radiation beam B, the controller CN may be operable to control the first and/or second pair of masking blades 36, 38, 32, 34 so as to vary the exposure field. It will be appreciated that an extent and/or position of the exposure field may be varied.

In some embodiments, the controller CN may be operable to control the first and/or second pair of masking blades 36, 38, 32, 34 so such that the exposure field for at least some image formation processes is different to the exposure field for a previous image formation process.

In some embodiments, the controller CN may be operable to control the first and/or second pair of masking blades 36, 38, 32, 34 so that at least one edge of the exposure field for each at least some image formation processes is shifted by an offset. For example, the offset may be of the order of 50 um. At least one of the edges of the exposure field may be stepped by such an offset every n exposure processes (for example every exposure process). In some embodiments all edges of the exposure field may be stepped by such an offset. A method implemented by the controller CN may use, for example, of the order of 5 different positions for each edge of the exposure field and the positions of each edge of the exposure field may be stepped or cycled through all of the (for example 5) different positions.

In some embodiments, the controller CN may be operable to control the first and/or second pair of masking blades 36, 38, 32, 34 such that the exposure field for the plurality of image formation processes is continuously varying. For example, a position of at least one edge of the exposure field may be continuously varying. For example, a position of at least one edge of the exposure field may oscillate over a range of positions about a nominal position. An amplitude of such oscillation may be of the order of 100 μm. In some embodiments all edges of the exposure field may be continuously varying.

In some embodiments, in order to illuminate the second portion 62 of the reticle and pellicle assembly 15 with the radiation beam B, the controller CN may be operable to control the first and/or second pair of masking blades 36, 38, 32, 34 such that a perimeter line of the exposure region is spread out over an extended area. For example, the perimeter line of the exposure region may be spread out over an area having a dimension of the order of 100 μm.

In some embodiments, in order to illuminate the second portion 62 of the reticle and pellicle assembly 15 with the radiation beam B, the controller CN may be operable to control the first and/or second pair of masking blades 36, 38, 32, 34 such that when forming an image of a reticle MA supported by the support structure MT on target region C of a substrate W that is adjacent to an edge of the substrate W, at least one of the masking blades 32, 34, 36, 38 that corresponds to an edge of the exposure field that is adjacent the edge of the substrate W may be positioned so as to enlarge the exposure field.

The target regions C that are adjacent to the edge of the substrate W may be referred to as edge target regions C or edge dies. It will be appreciated that such edge target regions C do not have adjacent target regions C on all sides. Rather, on at least one side (adjacent the edge of the substrate W), each edge target region C has no adjacent neighbour target region. For such edge target regions C (or dies) on the substrate W, the masking blades 32, 34, 36, 38 may be positioned so as to enlarge the exposure region. For example, for such edge target regions C (or dies) on the substrate W, the masking blades 32, 34, 36, 38 may be shifted by 1 mm or more relative to a nominal position so as to enlarge the exposure region. Advantageously, this will result in illumination of a portion 62 of the reticle and pellicle assembly 15 that is adjacent to the first portion 60 of the reticle and pellicle assembly 15 with the radiation beam B. If the masking blades 32, 34, 36, 38 are controlled in this way for all such edge dies, a portion 62 of the reticle and pellicle assembly 15 that substantially surrounds the first portion 60 of the reticle and pellicle assembly 15 can be illuminated with radiation B.

Forming an image of a reticle MA on a substrate a plurality of times may comprise forming an image of the reticle MA on a plurality of target regions C of the substrate W. Each of the plurality of target regions C may be generally rectangular. The plurality of target regions C may be arranged as a two-dimensional array.

In general, a duration of the periodic illumination of the second portion 62 of the reticle and pellicle assembly 15 with a radiation beam B may be sufficiently large to heat the second portion 62 of the pellicle to a desired temperature (for example above a threshold temperature above which hydrogen etching of the pellicle is negligible). In some embodiments, the desired temperature may be above 900 K. It will be appreciated that the time required for heating the pellicle to a desired temperature will be dependent on a power of the radiation beam while it is heating the pellicle.

In some embodiments, when illuminating the second portion 62 of the reticle and pellicle assembly 15 with the radiation beam B, the controller CN may be operable to heat up the pellicle to a temperature at which a hydrogen etching rate of the pellicle is negligible. For example, the controller CN may be operable to heat up the pellicle to a temperature above 800 K, for example a temperature above 900 K.

Some embodiments of the present disclosure relate to new pellicles for use in a lithographic apparatus that have been adapted so as to experience less plasma etching during use than existing pellicles and a lithographic apparatus LA of the type shown in FIG. 1 comprising such new pellicles, as now discussed with reference to FIGS. 16 to 19.

FIG. 16 shows a portion of a reticle and pellicle assembly in cross section. Part of a reticle MA, a pellicle frame 17 and a pellicle membrane 19 are all shown in FIG. 16. Also shown is a portion of a support 74 that facilitates a connection between the pellicle (frame 17 and membrane 19) and the reticle MA. The support 74 may comprise intermediate fixing members (known as studs) that are affixed to the patterning device (reticle). The intermediate fixing members (studs) on the patterning device (reticle) may engage (for example releasably engage) the attachment members of the pellicle frame 17. This is all indicated schematically as support 74. Also shown is one of the x masking blades 32.

A portion of the pellicle that can receive EUV radiation in use is indicated by arrow 76 in FIG. 16. This portion 76 of the pellicle that can receive EUV radiation may be generally equivalent to the first portion 60 of the reticle and pellicle assembly 15 (the part that is illuminated (EUV) radiation B to form an image of the reticle MA on the substrate W) discussed above. That is, the portion 76 of the pellicle may comprise a portion of the pellicle 19 that corresponds to an image formation portion of the reticle MA.

A portion of the pellicle that does not receive EUV radiation in use but which does receive the hydrogen plasma is indicated by arrow 78 in FIG. 16. This portion 78 of the pellicle may be generally equivalent to the part of the region 62 of the reticle and pellicle assembly 15 that surrounds the central portion 60 and which is discussed above. A position of peak etching intensity due to the hydrogen plasma is indicated by arrow 80 in the FIG. 16.

In use, the membrane 19 will receive a heat load from the EUV radiation used by the lithographic apparatus (for example EUV radiation) and potentially also from one or more heaters. However, the frame 17 will remain at a significantly lower temperature than the membrane 19 due to its significantly increased heat capacity and thermal inertia). The region of the membrane 19 that is in contact with the frame 17 has a reduced temperature due to the presence of the frame 17, and good thermal contact between the frame 17 and the membrane 19 (the frame 17 acts like a heat sink). However, it can be seen that there is an overlap between the portion 78 of the pellicle that does not receive EUV radiation but which does receive the hydrogen plasma and the frame 17.

Flash heating of this portion of the pellicle membrane 19 that overlaps both the frame 17 and the hydrogen plasma region will not be effective to increase the temperature of this portion of the membrane 19 above 600° C. because the frame 17 acts as a heat sink.

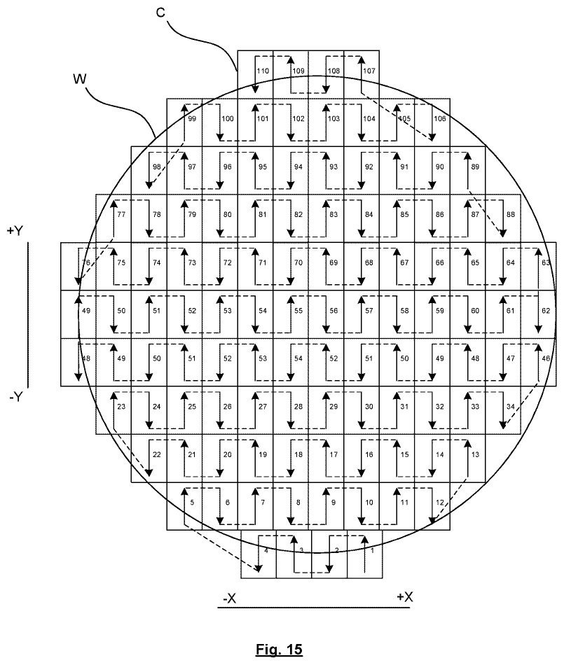

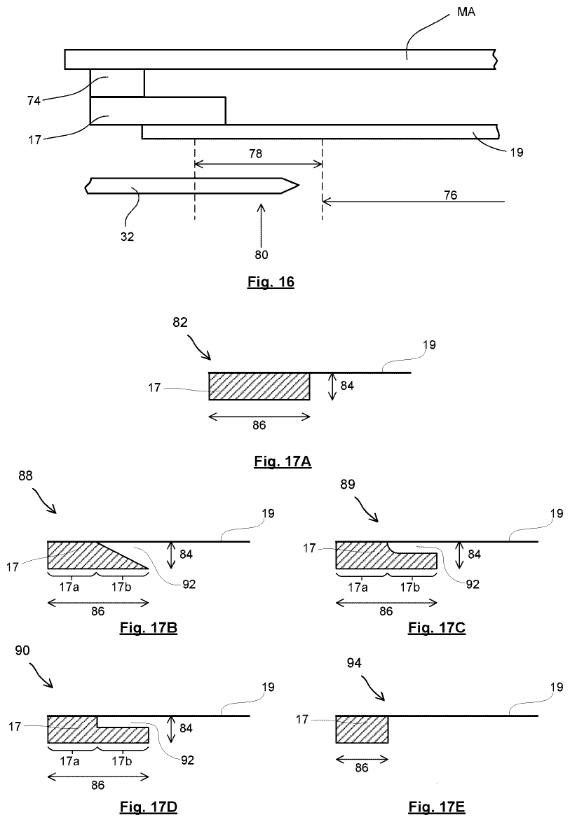

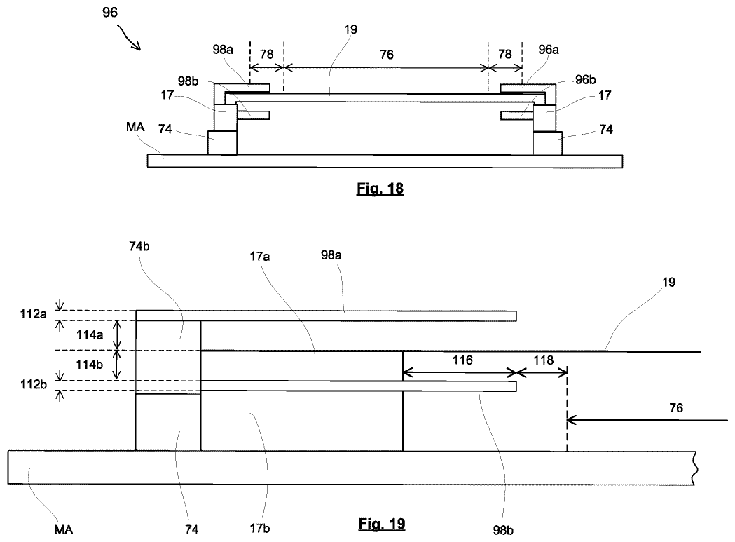

Some embodiments of the present disclosure relate to new pellicles for use in a lithographic apparatus LA that have been adapted so as to move a contact between the frame 17 and the membrane 19 outwards along at least one edge of the membrane 19, as now discussed with reference to FIGS. 17A to 17E.

FIG. 17A is a schematic cross section of a portion of a known pellicle 82. The known pellicle 82 comprises: a frame 17; and a membrane 19 surrounded by, and supported by, the frame 17. The membrane 19 is generally planar and defines a plane of the pellicle 82. The frame 17 is generally rectangular in cross section, having a thickness 84 that is generally perpendicular to the plane of the pellicle and a width 86 that is generally parallel to the plane of the pellicle.

FIGS. 17B to 17D are schematic cross sections of a portion of three new pellicles 88, 89, 90. The new pellicles 88, 89, 90 also each comprise: a frame 17; and a membrane 19 surrounded by, and supported by, the frame 17. The membrane 19 is generally planar and defines a plane of the pellicle 88, 89, 90. The frame 17 has a thickness 84 that is generally perpendicular to the plane of the pellicle and a width 86 that is generally parallel to the plane of the pellicle.

The frame 17 of each of the new pellicles 88, 89, 90 shown in FIGS. 17B to 17D may be considered to comprise an outer portion 17a and an inner portion 17b. The outer portion 17a of the frame 17 is in contact with the membrane 19 and, along at least one edge of the membrane 19, the inner portion 17b of the frame 17 is not in contact with the membrane 19. In particular, along at least one edge of the membrane 19, the inner portion 17b of the frame 17 has a reduced thickness 84 relative to the outer portion 17a of the frame 17 such that the inner portion 17b of the frame 17 is not in contact with the membrane 19.

In use, the membrane 19 will receive a heat load from the radiation used by the lithographic apparatus (for example EUV radiation) and from one or more heaters whereas the frame 17 will remain at a lower temperature. The region of the membrane 19 that is in contact with the frame 17 therefore has a reduced temperature due to the presence of the frame 17 (which has greater thermal inertia than the membrane 19 die to its larger dimensions). The new pellicles 88, 89, 90 shown in FIGS. 17B to 17D are advantageous as they allow for a contact between the frame 17 and the membrane 19 to be moved outwards along at least one edge of the membrane 19 without reducing a width 86 of the frame 17 (i.e. a dimension of the frame 17 that is generally parallel to the plane of the pellicle). This allows the frame 17 to retain a similar level of rigidity (for example as the known pellicle 82 shown in FIG. 17A) whilst moving the contact between the frame 17 and the membrane 19 outwards. Furthermore, advantageously, by moving the portion of the membrane 19 that is in contact with the frame 17 (and which, in use, is at a lower temperature than the rest of the membrane 19) outwards the membrane 19 is exposed to less, or even no, high intensity EUV-induced hydrogen plasma.

The new pellicles 88, 89, 90 shown in FIGS. 17B to 17D each define a recess 92 between the inner portion 17b of the frame 17 (having a reduced thickness 84) and the membrane 19. It will be appreciated that the recess 92 may have a variety of different shapes. For example, the recess 92 may have a generally uniform thickness (as shown in FIGS. 17C and 17D). The embodiment shown in FIG. 17C also comprises a fillet or rounded portion between the inner and outer portions 17a, 17b of the frame 17. This arrangement may reduce concentrations of stress in the frame 17.

Alternatively, the recess 92 formed between the inner portion 17b of the frame 17 (having a reduced thickness 84) and the membrane 19 may have a thickness 84 that varies from an inner edge of the frame 17 to the outer portion 17b of the frame 17 (as shown in FIG. 17B).

A width 86 of the inner portion 17b of the frame 17 (having a reduced thickness 84) may be chosen such that the portion of the membrane 19 that is in contact with the frame 17 (and which, in use, is at a lower temperature than the rest of the membrane 19) is not adjacent to a high intensity EUV-induced hydrogen plasma (i.e. does not overlap with the region portion 78 of the pellicle that does not receive EUV radiation but which does receive the hydrogen plasma and the frame 17; see FIG. 16).

A width 86 of the inner portion 17b of the frame 17 having a reduced thickness may be greater than 2 mm. In some embodiments, the width 86 of the inner portion 17b of the frame 17 may be greater than 2.2 mm. In some embodiments, the width 86 of the inner portion 17b of the frame 17 may be of the order of 2.5 mm.

FIG. 17E is a schematic cross section of a portion of another new pellicle 94. The new pellicle 94 shown in FIG. 17E is similar to the known pellicle 82 shown in FIG. 17A except the new pellicle 94 has a smaller width 86 than the known pellicle 82 shown in FIG. 17A. Again, this moves a contact point between the frame 17 and the membrane 19 outwards along at least one edge of the membrane 19, which reduces the etching of the pellicle.

Some embodiments of the present disclosure relate to a lithographic apparatus of the type shown in FIG. 1 comprising: a pellicle comprising: a frame 17; and a membrane 19 surrounded by, and supported by, the frame 17; a source of hydrogen; and an illumination system IL arranged to illuminate the pellicle with radiation; wherein a portion of the membrane 19 that is in contact with the frame 17 is disposed in a position that an EUV-induced hydrogen plasma does not diffuse to.

Advantageously, since the portion of the membrane 19 that is in contact with the frame 17 is disposed in a position that an EUV-induced hydrogen plasma does not diffuse to, the membrane 19 is subject to less etching from the hydrogen plasma. The pellicle of such a lithographic apparatus may comprise one of the pellicles 88, 89, 90, 94 shown in FIGS. 17B to 17E and/or a new pellicle of the type shown in FIGS. 18 and 19.

Some embodiments of the present disclosure relate to new pellicles for use in a lithographic apparatus LA that have been adapted so as to provide a shield to protect a peripheral portion of the membrane 19 from hydrogen plasma etching, as now discussed with reference to FIGS. 18 to 19.

FIG. 18 shows a new reticle and pellicle assembly 98 according to an embodiment of the present disclosure that comprises a new pellicle. FIG. 19 shows an enlarged portion of the new reticle and pellicle assembly 98 shown in FIG. 18. The new pellicle is for use in a lithographic apparatus LA and comprises: a frame 17; a membrane 19 surrounded by, and supported by, the frame 17; and a shield 98a, 98b adjacent to a peripheral portion of the membrane 19 that is adjacent the frame 17. The membrane 19 is generally planar and defines a plane of the pellicle. The shield 98a, 98b is spaced apart from the membrane 19 in a direction generally perpendicular to the plane of the pellicle.

In the embodiment shown in FIGS. 18 and 19, the shield comprises: a first shield member 98a adjacent to a first surface of the peripheral portion of the membrane 19 and second shield member 98b adjacent to a second surface of the peripheral portion of the membrane 19. The first surface may be a surface of the pellicle that, in use, faces away from the reticle MA (and may be referred to as an upper or front surface of the pellicle). The second surface may be a surface of the pellicle that, in use, faces towards the reticle MA (and may be referred to as a lower or rear surface of the pellicle). Alternative embodiments may comprise only one of the first and second shield members 98a, 98b.

The new pellicle shown in FIGS. 18 and 19 is advantageous as the shield 98a, 98b can protect the pellicle from etching by plasma (for example EUV-induced hydrogen plasma) in use, for example in an EUV lithographic apparatus LA.

Conventional thought may be that the reticle masking blades 32, 34, 36, 38 may act as a plasma shield for the pellicle. However, recently it has been found that the region of highest etching on CNT membranes is outside the exposure area (i.e. the portion 76 of the pellicle that can receive EUV radiation), under the reticle masking blades 32, 34, 36, 38 (indicating that the reticle masking blades 32, 34, 36, 38 do not provide effective plasma shielding of the pellicle). It is thought that a distance between the reticle masking blades 32, 34, 36, 38 and the pellicle membrane 19 is too large to provide an effective shielding function. Although in use there is typically not a large amount of space between the pellicle membrane 19 and other components (for example the reticle masking blades 32, 34, 36, 38) it is thought that there is sufficient space for a relatively thin shield 98a, 98b, allowing the new pellicle shown in FIGS. 18 and 19 to be used in existing lithographic apparatus LA.

The shield 98a, 98b may extend past the border of the pellicle but remain outside the quality area (or a portion of the pellicle that corresponds to an image formation region of the reticle MA).

The first shield member 98a and/or the second shield member 98b may be supported either directly or indirectly by either the frame 17 or the support 74.

The support 74 for the pellicle that facilitates connection to the reticle MA may comprise an additional or extended portion 74b that extends away from the reticle MA further than the membrane 19. The first shield member 98a may be provided as a cantilever structure extending from this additional or extended portion 74b.

The second shield member 98b may be provided as a cantilever structure extending from the frame 17. As shown in FIG. 19, this may be achieved by providing the frame as two frame portions 17a, 17b with the second shield member 98b sandwiched between the two frame portions 17a, 17b and extending therefrom adjacent the membrane 19.

It will be appreciated that the new pellicle shown in FIGS. 18 and 19 may comprise any of the features of the new pellicles shown in FIGS. 17B to 17E as desired.

It may be desirable for the shield 98a, 98b to be as close to the surface of the membrane 19 as possible, since this will minimize the amount of plasma diffusing under the shield 98a, 98b (i.e. between the shield 98a, 98b and the membrane 19), maximizing the plasma shielding. In general, it may be desirable for a distance between the shield 98a, 98b and the surface of the membrane 19 to be less than the Debye length of the plasma (which may be less than 1 mm or, during the EUV pulse, may be less than 0.2 mm). It may also be desirable for the shield 98a, 98b to be far enough from the surface of the membrane 19 to allow for any sag of the membrane 19 without risk of the shield 98a, 98b contacting the surface of the membrane 19.

It will be appreciated that the first shield member 98a and the second shield member 98b may be disposed at different distances from the membrane 19. Alternatively, the first shield member 98a and the second shield member 98b may be disposed at substantially the same distance from the membrane 19.

A distance between the shield 98a, 98b and the membrane 19 may be less than 1 mm. It will be appreciated that a distance 114a between the first shield member 98a and the membrane 19 may be less than 1 mm and/or a distance 114 b between the second shield member 98 b and the membrane 19 is less than 1 mm. In particular, a distance between the front surface of the membrane 19 and the shield member 98a adjacent thereto may be less than 1 mm. A distance 114a between the first shield member 98a and the membrane 19 may be between 200 μm and 1000 μm. A distance 114a between the first shield member 98a and the membrane 19 may be between 400 μm and 800 μm. A distance 114b between the second shield member 98b and the membrane 19 may be between 200 μm and 1000 μm. A distance 114b between the second shield member 98b and the membrane 19 may be between 400 μm and 800 μm.

The shield 98a, 98b may have a thickness of less than 1 mm. A thickness 112a of the first shield member 98a may be of the order of 100 μm to 300 μm. A thickness 112b of the second shield member 98b may be of the order of 100 μm to 300 μm. In some embodiments, the shield members 98a, 98b may have thicknesses 112a, 112b of around 200 μm or less. The thicknesses 112a, 112b of the shield members 98a, 98b may be chosen to be something easily commercially available.

The shield 98a, 98b may extend a distance 116 away from the frame 17 in a plane of the membrane 19. The distance 116 may, for example, be of the order of 1 mm to 1.5 mm.

Preferably, the shield 98a, 98b may extend to cover a portion of the membrane 19 that, with no shield present, would be adjacent to the plasma in use but which does not receive EUV radiation. The shield 98a, 98b may remain a distance 118 away from a quality area of the pellicle 78 (i.e. a portion of the pellicle that corresponds to an image formation region of the reticle MA) so that the shield does not interfere with the EUV light cone. For example, the distance 118 may be of the order of 0.5 mm to 1.5 mm.

The shield 98a, 98b may be formed from a material that is transparent to a wavelength of radiation that, in use, is used to periodically heat the pellicle.

For example, the shield 98a, 98b may be formed from a material that is transparent to infrared (IR) and/or deep ultra violet (DUV) radiation. This allows the shield 98a, 98b to protect the pellicle from plasma while still allowing the membrane 19 to be heated using such radiation periodically.

The shield 98a, 98b may be formed from a material that is inert in hydrogen plasma.

The shield 98a, 98b may comprise sapphire (Al₂O₃). For example, the shield 98a, 98b may comprise a sapphire (Al₂O₃) coated glass material. Alternatively, the shield 98a, 98b may be formed from sapphire.

Some embodiments of the present disclosure relate to a lithographic apparatus LA of the type shown in FIG. 1 and comprising: a pellicle comprising: a frame 17; a membrane 19 surrounded by, and supported by, the frame 17; and a shield 98a, 98b adjacent to a peripheral portion of the membrane 19 that is adjacent the frame 17; a source of hydrogen; and an illumination system IL arranged to illuminate the pellicle with radiation; wherein the shield 98a, 98b is adjacent to a portion of the membrane 19 that in the absence of such a shield an EUV-induced hydrogen plasma would diffuse to.

Advantageously, since the shield 98a, 98b is adjacent to a portion of the membrane that in the absence of such a shield 98a, 98b an EUV-induced hydrogen plasma would diffuse to, the shield 98a, 98b protects the membrane 19 from the plasma (and associated plasma etching) that would be present in the absence of such a shield 98a, 98b. The pellicle of such a lithographic apparatus LA may comprise a new pellicle 88, 89, 90, 94 as shown in FIGS. 17B to 17E and/or a new pellicle of the type shown in FIGS. 18 and 19.

References to a mask or reticle in this document may be interpreted as references to a patterning device (a mask or reticle is an example of a patterning device) and the terms may be used interchangeably. In particular, the term mask assembly is synonymous with reticle assembly and patterning device assembly.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

The term “EUV radiation” may be considered to encompass electromagnetic radiation having a wavelength within the range of 4-20 nm, for example within the range of 13-14 nm. EUV radiation may have a wavelength of less than 10 nm, for example within the range of 4-10 nm such as 6.7 nm or 6.8 nm.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims and clauses set out below.

1. A lithographic method comprising:
forming an image of a reticle on a substrate a plurality of times, each such image formation process comprising:
illuminating a first portion of a reticle and pellicle assembly with a radiation beam; and collecting radiation scattered by the reticle and projecting it onto a target region of a substrate using projection optics; and
periodically illuminating a second portion of the reticle and pellicle assembly with a radiation beam, the second portion of the reticle and pellicle assembly at least partially surrounding the first portion.

2. The method of clause 1 wherein periodically illuminating the second portion of the reticle and pellicle assembly with a radiation beam is achieved by periodically illuminating an enlarged exposure field.

3. The method of clause 1 or clause 2 wherein periodically illuminating the second portion of the reticle and pellicle assembly with a radiation beam is achieved by varying the exposure field.

4. The method of clause 3 wherein the exposure field for at least some image formation processes is different to the exposure field for a previous image formation process.

5. The method of clause 4 wherein at least one edge of the exposure field for each at least some image formation processes is shifted by an offset.

6. The method of clause 3 wherein the exposure field for the plurality of image formation processes is continuously varying.

7. The method of any preceding clause wherein during each image formation process at least one masking blade is used so as to mask an adjacent target region of the substrate from the radiation beam.

8. The method of clause 7 when dependent either direction or indirectly on clause 2 or clause 3 wherein illuminating an enlarged exposure field or varying the exposure field is achieved by controlling the at least one masking blade.

9. The method of clause 7 or clause 8 when a position of the at least one reticle masking blade is manipulated such that a perimeter line of the exposure region is spread out over an extended area.

10. The method of any one of clauses 7 to 9 wherein four masking blades are used during the exposure of each target region so as to define the exposure field and wherein for each target region adjacent to an edge of the substrate at least one of the masking blades that corresponds to an edge of the exposure field that is adjacent the edge of the substrate is positioned so as to enlarge the exposure field.

11. The method of any preceding clause wherein forming an image of a reticle on a substrate a plurality of times comprises forming an image of the reticle on a plurality of target regions of the substrate, the plurality of target regions arranged as a two-dimensional array, wherein the two-dimensional array of target regions are exposed one row at a time and wherein the rows are not exposed in order.

12. The method of any preceding clause wherein each image formation process comprises a scanning exposure in which the reticle and pellicle assembly is moved in a scanning direction relative to the radiation beam.

13. The method of any preceding clause when dependent either directly or indirectly on clause 2 and wherein when the enlarged exposure field is periodically illuminated the radiation scattered from the reticle and pellicle assembly is not projected onto the substrate.

14. The method of any preceding clause wherein periodically illuminating a second portion of the reticle and pellicle assembly with a radiation beam comprises exposing the second portion to EUV radiation to heat up the pellicle to a temperature at which a hydrogen etching rate of the pellicle is negligible.

15. The method of any preceding clause wherein periodically illuminating the second portion of the reticle and pellicle assembly with a radiation beam is such that the second portion of the reticle and pellicle assembly is illuminated once per substrate.

16. The method of any preceding clause wherein periodically illuminating the second portion of the reticle and pellicle assembly with a radiation beam is such that the second portion of the reticle and pellicle assembly is illuminated once per each row of target regions on a substrate.

17. A lithographic component of a lithographic apparatus, the lithographic component comprising:
a support structure constructed to support a reticle and pellicle assembly for receipt of a radiation beam; and
a controller operable to control the support structure and/or the radiation beam so as to:
   (a) form an image of a reticle supported by the support structure on a substrate a plurality of times, each such image formation process comprising: illuminating a first portion of a reticle and pellicle assembly with the radiation beam; and projecting radiation scattered by the reticle onto a target region of a substrate using projection optics; and
   (b) periodically illuminate a second portion of the reticle and pellicle assembly with the radiation beam, the second portion of the reticle and pellicle assembly at least partially surrounding the first portion.

18. The lithographic component of clause 17, wherein the controller is operable to implement the method of any one of clauses 1 to 16.

19. The lithographic component of clause 17 or clause 18 further comprising a scanning mechanism operable to move the support structure relative to the radiation beam in a scanning direction.

20. The lithographic component of any one of clauses 17 to 19 further comprising:

a first pair of masking blades arranged to define an extent of an exposure region in a first direction; and a second pair of masking blades arranged to define an extent of an exposure region in a second direction.

21. The lithographic component of clause 20 when dependent on clause 19 wherein the first direction is the scanning direction and wherein in order to form an image of a reticle supported by the support structure on target region of a substrate, the controller is operable to:
control the scanning mechanism so as to move a reticle supported by the support structure through an exposure region; and
control a position of the first pair of masking blades so as to mask an adjacent target region of the substrate from the radiation beam.

22. The lithographic component of any one of clauses 17 to 21 when dependent either directly or indirectly on clause 20 wherein in order to illuminate the second portion of the reticle and pellicle assembly with the radiation beam, the controller is operable to control the first and/or second pair of masking blades so as to illuminate an enlarged exposure field.

23. The lithographic component of any one of clauses 17 to 22 when dependent either directly or indirectly on clause 20 wherein in order to illuminate the second portion of the reticle and pellicle assembly with the radiation beam, the controller is operable to control the first and/or second pair of masking blades so as to vary the exposure field.

24. The lithographic component of clause 23 wherein the controller is operable to control the first and/or second pair of masking blades so such that the exposure field for at least some image formation processes is different to the exposure field for a previous image formation process.

25. The lithographic component of clause 24 wherein the controller is operable to control the first and/or second pair of masking blades so that at least one edge of the exposure field for each at least some image formation processes is shifted by an offset.

26. The lithographic component of clause 23 wherein the controller is operable to control the first and/or second pair of masking blades such that the exposure field for the plurality of image formation processes is continuously varying.

27. The lithographic component of any one of clauses 17 to 26 when dependent either directly or indirectly on clause 20 wherein in order to illuminate the second portion of the reticle and pellicle assembly with the radiation beam, the controller is operable to control the first and/or second pair of masking blades such that a perimeter line of the exposure region is spread out over an extended area.

28. The lithographic component of any one of clauses 17 to 27 when dependent either directly or indirectly on clause 20 wherein in order to illuminate the second portion of the reticle and pellicle assembly with the radiation beam, the controller is operable to control the first and/or second pair of masking blades such that when forming an image of a reticle supported by the support structure on a target region of a substrate that is adjacent to an edge of the substrate, at least one of the masking blades that corresponds to an edge of the exposure field that is adjacent the edge of the substrate is positioned so as to enlarge the exposure field.

29. The lithographic component of any one of clauses 17 to 28 wherein when illuminating the second portion of the reticle and pellicle assembly with the radiation beam, the controller is operable to heat up the pellicle to a temperature at which a hydrogen etching rate of the pellicle is negligible.

30. A lithographic apparatus comprising the component of any one of clauses 17 to 29.

31. The lithographic apparatus of clause 30 further comprising:
an illumination system configured to condition the radiation beam received by the reticle and pellicle assembly;
a substrate table constructed to support a substrate; and
a projection system configured to receive the radiation beam from the reticle and pellicle assembly and to project said radiation beam onto the substrate.

32. A pellicle for use in a lithographic apparatus, pellicle comprising:
a frame; and
a membrane surrounded by, and supported by, the frame;
wherein the membrane is generally planar and defines a plane of the pellicle;

wherein the frame has a thickness that is generally perpendicular to the plane of the pellicle and a width that is generally parallel to the plane of the pellicle; and
wherein, in the plane of the pellicle, an outer portion of the frame is in contact with the membrane and, along at least one edge of the membrane, an inner portion of the frame has a reduced thickness relative to the outer portion of the frame such that the inner portion of the frame is not in contact with the membrane.

33. The pellicle of clause 32 wherein a recess formed between the inner portion of the frame having a reduced thickness and the membrane has a generally uniform thickness.

34. The pellicle of clause 32 wherein a recess formed between the inner portion of the frame having a reduced thickness and the membrane has a thickness that varies from an inner edge of the frame to the outer portion of the frame.

35. The pellicle of any one of clauses 32 to 34 wherein a width of the inner portion of the frame having a reduced thickness is greater than 2.2 mm.

36. A lithographic apparatus comprising:
a pellicle comprising: a frame; and a membrane surrounded by, and supported by, the frame;
a source of hydrogen; and
an illumination system arranged to illuminate the pellicle with radiation;
wherein a portion of the membrane that is in contact with the frame is disposed in a position that an EUV-induced hydrogen plasma does not diffuse to.

37. A pellicle for use in a lithographic apparatus, pellicle comprising:
a frame;
a membrane surrounded by, and supported by, the frame; and
a shield adjacent to a peripheral portion of the membrane that is adjacent the frame;
wherein the membrane is generally planar and defines a plane of the pellicle; and
wherein the shield is spaced apart from the membrane in a direction generally perpendicular to the plane of the pellicle.

38. The pellicle of clause 37 wherein the shield comprises a first shield member adjacent to a first surface of the peripheral portion of the membrane and second shield member adjacent to a second surface of the peripheral portion of the membrane.

39. The pellicle of clause 37 or clause 38 wherein a distance between the shield and the membrane is less than 1 mm.

40. The pellicle of any one of clauses 37 to 39 wherein the shield has a thickness of less than 1 mm.

41. The pellicle of any one of clauses 37 to 40 wherein the shield extends of the order of 1 mm to 1.5 mm away from the frame, over the membrane.

42. The pellicle of any one of clauses 37 to 41 wherein the shield is formed from a material that is transparent to a wavelength of radiation that, in use, is used to periodically heat the pellicle.

43. The pellicle of any one of clauses 37 to 42 wherein the shield is formed from a material that is inert in hydrogen plasma.

44. The pellicle of any one of clauses 37 to 43 wherein the shield comprises sapphire (Al₂O₃).

45. A lithographic apparatus comprising:
a pellicle comprising: a frame; a membrane surrounded by, and supported by, the frame; and a
shield adjacent to a peripheral portion of the membrane that is adjacent the frame;
a source of hydrogen; and
an illumination system arranged to illuminate the pellicle with radiation;
wherein the shield is adjacent to a portion of the membrane that in the absence of such a shield an EUV-induced hydrogen plasma would diffuse to.

1. A lithographic component of a lithographic apparatus, the lithographic component comprising:
a support structure constructed to support a reticle and pellicle assembly for receipt of a radiation beam; and
a controller configured to control the support structure and/or the radiation beam so as to:
form an image of a reticle supported by the support structure on a substrate a plurality of times, each such image formation process comprising:
illumination of a first portion of a reticle and pellicle assembly with the radiation beam; and
projection of radiation scattered by the reticle onto a target region of a substrate using projection optics; and
periodically illuminate a second portion of the reticle and pellicle assembly with the radiation beam, the second portion of the reticle and pellicle assembly at least partially surrounding the first portion.

2. (canceled)

3. The lithographic component of claim 1, further comprising a scanning mechanism operable to move the support structure relative to the radiation beam in a scanning direction.

4. The lithographic component of claim 1, further comprising:
a first pair of masking blades arranged to define an extent of an exposure region in a first direction; and
a second pair of masking blades arranged to define an extent of an exposure region in a second direction.

5. The lithographic component of claim 4, further comprising a scanning mechanism operable to move the support structure relative to the radiation beam in a scanning direction and wherein the first direction is the scanning direction and wherein in order to form an image of a reticle supported by the support structure on target region of a substrate, the controller is configured to:
control the scanning mechanism so as to move a reticle supported by the support structure through an exposure region; and
control a position of the first pair of masking blades so as to mask an adjacent target region of the substrate from the radiation beam.

6. The lithographic component of claim 4, wherein in order to illuminate the second portion of the reticle and pellicle assembly with the radiation beam, the controller is configured to control the first and/or second pair of masking blades so as to illuminate an enlarged exposure field.

7. The lithographic component of claim 4, wherein in order to illuminate the second portion of the reticle and pellicle assembly with the radiation beam, the controller is configured to control the first and/or second pair of masking blades so as to vary the exposure field.

8. The lithographic component of claim 7, wherein the controller is configured to control the first and/or second pair of masking blades so such that the exposure field for at least some image formation processes is different to the exposure field for a previous image formation process.

9. The lithographic component of claim 8, wherein the controller is configured to control the first and/or second pair of masking blades so that at least one edge of the exposure field for each at least some image formation processes is shifted by an offset.

10. The lithographic component of claim 7, wherein the controller is configured to control the first and/or second pair of masking blades such that the exposure field for the plurality of image formation processes is continuously varying.

11. The lithographic component of claim 4, wherein in order to illuminate the second portion of the reticle and pellicle assembly with the radiation beam, the controller is configured to control the first and/or second pair of masking blades such that a perimeter line of the exposure region is spread out over an extended area.

12. The lithographic component of claim 4, wherein in order to illuminate the second portion of the reticle and pellicle assembly with the radiation beam, the controller is configured to control the first and/or second pair of masking blades such that when forming an image of a reticle supported by the support structure on a target region of a substrate that is adjacent to an edge of the substrate, at least one of the masking blades that corresponds to an edge of the exposure field that is adjacent the edge of the substrate is positioned so as to enlarge the exposure field.

13. The lithographic component of claim 1, wherein when illuminating the second portion of the reticle and pellicle assembly with the radiation beam, the controller is configured to heat up the pellicle to a temperature at which a hydrogen etching rate of the pellicle is negligible.

14. A lithographic apparatus comprising the component of claim 1.

15. The lithographic apparatus of claim 14, further comprising:
an illumination system configured to condition the radiation beam received by the reticle and pellicle assembly;
a substrate table constructed to support a substrate; and
a projection system configured to receive the radiation beam from the reticle and pellicle assembly and to project the said radiation beam onto the substrate.

16. A lithographic method comprising:
forming an image of a reticle on a substrate a plurality of times, each such image formation process comprising:
illuminating a first portion of a reticle and pellicle assembly with a radiation beam; and
projecting radiation scattered by the reticle onto a target region of a substrate using projection optics; and
periodically illuminating a second portion of the reticle and pellicle assembly with a radiation beam, the second portion of the reticle and pellicle assembly at least partially surrounding the first portion.

17. The method of claim 16, wherein periodically illuminating the second portion of the reticle and pellicle assembly with a radiation beam is achieved by periodically illuminating an enlarged exposure field.

18.-24. (canceled)

25. The method of claim 16, wherein four masking blades are used during the exposure of each target region so as to define the exposure field and wherein for each target region adjacent to an edge of the substrate at least one of the masking blades that corresponds to an edge of the exposure field that is adjacent the edge of the substrate is positioned so as to enlarge the exposure field.

26. The method of claim 16, wherein forming an image of a reticle on a substrate a plurality of times comprises forming an image of the reticle on a plurality of target regions of the substrate, the plurality of target regions arranged as a two-dimensional array, wherein the two-dimensional array of target regions are exposed one row at a time and wherein the rows are not exposed in order.

27.-28. (canceled)

29. The method of claim 16, wherein periodically illuminating a second portion of the reticle and pellicle assembly with a radiation beam comprises exposing the second portion to radiation to heat up the pellicle to a temperature at which a hydrogen etching rate of the pellicle is negligible.

30. The method of claim 16, wherein periodically illuminating the second portion of the reticle and pellicle assembly with a radiation beam is such that the second portion of the reticle and pellicle assembly is illuminated once per substrate.

31. (canceled)
